(19) United States
(12) Patent Application Publication
(10) Pub. No.: US 2018/0040487 A1
(43) Pub. Date: Feb. 8, 2018

(54) MANUFACTURING METHOD OF SEMICONDUCTOR DEVICE AND SEMICONDUCTOR DEVICE

(71) Applicant: Renesas Electronics Corporation, Tokyo (JP)

(72) Inventor: Noriyuki TAKAHASHI, Takasakiishi, Gunma (JP)

(73) Assignee: Renesas Electronics Corporation, Tokyo (JP)

(21) Appl. No.: 15/553,133

(22) PCT Filed: Jul. 2, 2015
(86) PCT No.: PCT/JP2015/069194

§ 371 Date: Aug. 23, 2017

(51) Int. Cl. H01L 21/56; H01L 23/31; H01L 23/00; H01L 23/495

(52) U.S. Cl. CPC H01L 21/565; H01L 23/49555; H01L 23/49503; H01L 23/3107; H01L 24/97; H01L 21/561; H01L 24/48; H01L 24/32; H01L 24/73; H01L 2224/32245; H01L 2224/48091; H01L 2224/48106; H01L 2224/48247; H01L 2224/73265; H01L 24/85; H01L 24/83; H01L 24/92; H01L 2224/92247; H01L 21/78

(57) ABSTRACT

In the manufacturing method of a semiconductor device according to an embodiment, a suspension lead is connected to a chip mounting section on which a semiconductor chip is mounted. Also, the suspension lead includes: a first tab connection section connected to the chip mounting section and extending in a first direction; a first branch section provided at a position higher than the first tab connection section with respect to a chip mounting surface and branching in a plurality of directions intersecting the first direction; and a plurality of first exposed-surface connection sections provided at positions higher than the first branch section and each having one end connected to a portion exposed from a sealing body. In addition, the suspension lead includes: a first offset section connected to the first tab connection section and the first branch section; and a plurality of second offset sections each having one end connected to the first branch section and the other end connected to each of the plurality of first exposed-surface connection sections.

### TECHNICAL FIELD

The present invention relates to a semiconductor device having a structure in which a part of a chip mounting section on which a semiconductor chip is mounted is exposed from a sealing body that seals the semiconductor chip and a manufacturing method thereof.

### BACKGROUND ART

Japanese Patent Application Laid-Open Publication No. H08-37270 (Patent Document 1) and Japanese Patent Application Laid-Open Publication No. 2010-177510 (Patent Document 2) describe suspension leads connected to short sides of a tab having a rectangular planar shape. In the suspension lead described in Patent Document 1, the side opposite to a portion connected to a tab is bifurcated and an offset section is provided in a portion that is not bifurcated. In addition, in the suspension lead described in Patent Document 2, the side opposite to a portion connected to a tab is bifurcated and an offset section is provided in each of the bifurcated portions.

Also, Japanese Patent Application Laid-Open Publication No. H06-302745 (Patent Document 3) and Japanese Patent Application Laid-Open Publication No. H11-340403 (Patent Document 4) describe a configuration in which a gate section is provided in a die disposed on a lower side of a lead frame and no gate section is provided in a die disposed on an upper side of the lead frame in the process of resin sealing.

### RELATED ART DOCUMENTS

### Patent Documents

Patent Document 1: Japanese Patent Application Laid-Open Publication No. H08-37270

Patent Document 2: Japanese Patent Application Laid-Open Publication No. 2010-177510

Patent Document 3: Japanese Patent Application Laid-Open Publication No. H06-302745

Patent Document 4: Japanese Patent Application Laid-Open Publication No. H11-340403

### SUMMARY OF THE INVENTION

### Problems to be Solved by the Invention

There is a technique of exposing a lower surface (a surface opposite to a chip mounting surface) of a die pad, which is a chip mounting section on which a semiconductor chip is mounted, from a sealing body. In order to expose the lower surface of the die pad, it is necessary to bend the suspension lead connected to the die pad. However, according to the study by the inventor of the present application, it has been found that there is a problem from the viewpoint of the strength of the suspension lead for supporting the die pad, depending on the degree of bending of the suspension lead.

Other problems and novel features will become apparent from the description of the present specification and the accompanying drawings.

### Means for Solving the Problems

In the manufacturing method of a semiconductor device according to an embodiment, a suspension lead is connected to a chip mounting section on which a semiconductor chip is mounted. The suspension lead includes a first tab connection section connected to the chip mounting section and extending in a first direction, a first branch section provided at a position higher than the first tab connection section with respect to the chip mounting surface and branching in a plurality of directions intersecting the first direction, and a plurality of first exposed-surface connection sections provided at positions higher than the first branch section and each having one end connected to a portion exposed from a sealing body. Also, the suspension lead further includes a first offset section connected to the first tab connection section and the first branch section and a plurality of second offset sections each having one end connected to the first branch section and the other end connected to each of the plurality of first exposed-surface connection sections.

### Effects of the Invention

According to the above-described embodiment, the reliability of the semiconductor device can be improved.

### BRIEF DESCRIPTIONS OF THE DRAWINGS

FIG. 1 is a perspective view of a semiconductor device according to an embodiment;

FIG. 2 is a bottom view of the semiconductor device shown in FIG. 1;

FIG. 3 is a plan view showing an internal structure of the semiconductor device in a state where the sealing body shown in FIG. 1 is removed;

FIG. 4 is a cross-sectional view taken along line A-A of FIG. 3;

FIG. 5 is a cross-sectional view taken along line B-B of FIG. 3;

FIG. 6 is a cross-sectional view showing a mounting structure in which the semiconductor device shown in FIG. 4 is mounted on a mounting board;

FIG. 7 is an enlarged perspective view showing one of two suspension leads shown in FIG. 3 in an enlarged manner;

FIG. 8 is an enlarged cross-sectional view taken along line A-A of FIG. 7;

FIG. 9 is an enlarged cross-sectional view taken along line B-B of FIG. 7;

FIG. 10 is an explanatory diagram showing an assembly flow of the semiconductor device shown in FIG. 1;

FIG. 11 is a plan view showing an entire structure of a lead frame prepared in a lead frame preparation process of FIG. 10;

FIG. 12 is an enlarged plan view of the periphery of one device region among a plurality of device regions shown in FIG. 11;

FIG. 13 is an enlarged plan view showing a state in which a semiconductor chip is mounted on a die pad shown in FIG. 12 via a bonding material;

FIG. 14 is an enlarged cross-sectional view taken along line A-A of FIG. 13;

FIG. 15 is an enlarged plan view showing a state in which the semiconductor chip and a plurality of leads shown in FIG. 13 are electrically connected via wires;

FIG. 16 is an enlarged cross-sectional view taken along line A-A of FIG. 15;

FIG. 17 is a plan view showing a state in which a sealing body is formed in each device region of the lead frame shown in FIG. 15;

FIG. 18 is an enlarged cross-sectional view taken along line A-A of FIG. 17;

FIG. 19 is a plan view showing a surface on the opposite side of the lead frame shown in FIG. 17;

FIG. 20 is an enlarged cross-sectional view showing a state in which the lead frame is disposed in a molding die for molding a sealing body in the cross section taken along line A-A of FIG. 17;

FIG. 21 is an enlarged plan view showing a state in which each connection section of a gate resin and a vent resin shown in FIG. 19 is broken to form through holes penetrating the lead frame in a thickness direction;

FIG. 22 is an explanatory view schematically showing a resin supply direction from a gate section in a sealing process;

FIG. 23 is an enlarged plan view of the periphery of the gate section shown in FIG. 19;

FIG. 24 is an enlarged cross-sectional view taken along line A-A of FIG. 23;

FIG. 25 is an enlarged plan view of the periphery of a through gate section shown in FIG. 19;

FIG. 26 is an enlarged cross-sectional view showing a state in which metal films are formed on exposed surfaces of the leads and the die pad shown in FIG. 21;

FIG. 27 is an enlarged plan view showing a state in which a plurality of leads shown in FIG. 26 are divided and shaped;

FIG. 28 is an enlarged plan view showing a state in which a plurality of device regions of the lead frame shown in FIG. 27 are separated from each other;

FIG. 29 is a side view of the semiconductor device shown in FIG. 1 seen from a short side;

FIG. 30 is an enlarged cross-sectional view showing an examination example for the suspension lead shown in FIGS. 8 and 9;

FIG. 31 is an enlarged cross-sectional view showing another examination example for the suspension lead shown in FIGS. 8 and 9; and

FIG. 32 is an explanatory view schematically showing a state in which a pressing force is applied to the suspension lead having the structure shown in FIG. 31 in a sealing process.

### DETAILED DESCRIPTION OF PREFERRED EMBODIMENTS

(Explanation of Description Form, Basic Terminology and Usage in the Present Application)

In the present application, the embodiments will be described in a plurality of sections when required as a matter of convenience. However, these sections are not irrelevant to each other unless otherwise stated, and a part of one example relates to the other example as details or a part or the entire of a modification example regardless of the order of description. Also, the repetitive description of similar components will be omitted in principle. Further, the components in the embodiments are not always indispensable unless otherwise stated or except the case where the components are theoretically indispensable in principle or the components are obviously indispensable from the context.

Similarly, in the description of the embodiments, the phrase “X made of A” for a material, a composition or the like is not intended to exclude those containing elements other than A unless otherwise specified and except for the case where it clearly contains only A from the context. For example, as for a component, it means “X containing A as a main component”. For example, a “silicon member” or the like is not limited to pure silicon and it is obvious that the silicon member includes a member made of silicon germanium (Site) alloy, a member made of multicomponent alloy containing silicon as a main component, and a member containing other additives or the like. In addition, gold plating, a Cu layer, nickel plating or the like includes a member containing gold, Cu, nickel or the like as a main component as well as a pure one unless otherwise indicated clearly.

In addition, when referring to a specific value or amount, a value or amount larger or smaller than the specific value or amount is also applicable unless otherwise stated or except for the case where the value or amount is logically limited to the specific value or amount and the value or amount is apparently limited to the specific value or amount from the context.

Further, in the drawings for the embodiments, the same or similar components are denoted by the same or similar reference character or reference number, and the descriptions thereof are not repeated in principle.

In the present application, the term “upper surface” or “lower surface” is sometimes used, but since there are various modes in the mounting of the semiconductor package, the upper surface may be sometimes arranged below the lower surface, for example, after mounting the semiconductor package. In the present application, the surface of the semiconductor chip on the side of the element formation surface is described as the front surface, and the surface on the side opposite to the front surface is described as the back surface. Further, the surface of the wiring board on the side of the chip mounting surface is described as the upper surface or the front surface, and the surface located on the side opposite to the upper surface is described as the lower surface.

In addition, in the attached drawings, hatching may be omitted even in cross sections in the case where the hatchings make the drawings complicated on the contrary or discrimination from void is clear. In relation to this, when it is clear from the description or the like, an outline of a background may be omitted even in a planarly closed hole. Furthermore, even in the cases other than the cross section, hatching or dot patterns may be applied so as to clarify a boundary of regions or clarify that a portion is not a vacant space.

In the embodiments described below, a SOP type semiconductor device is taken as an example of a semiconductor device in which a plurality of leads which are external terminals are exposed from a sealing body in a lower surface (mounting surface) of the sealing body.

<Semiconductor Device>

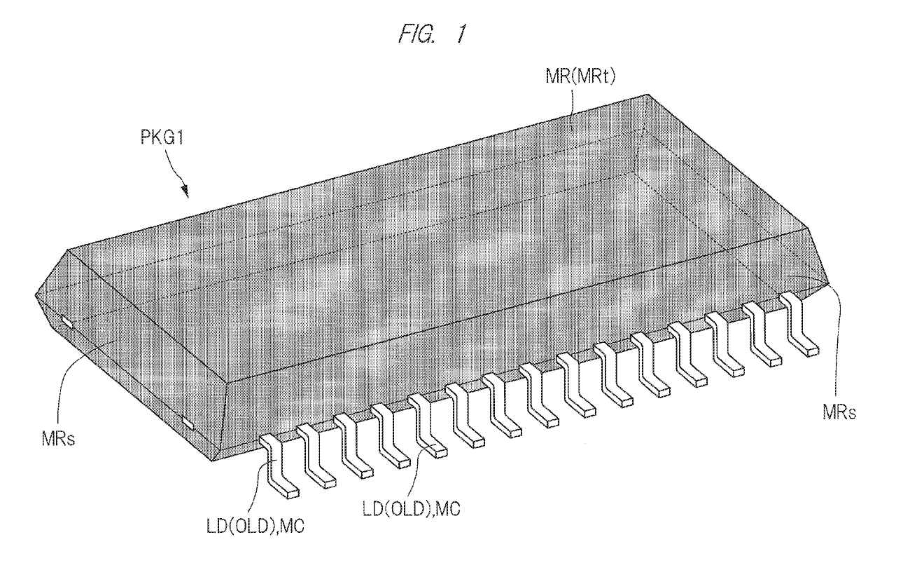

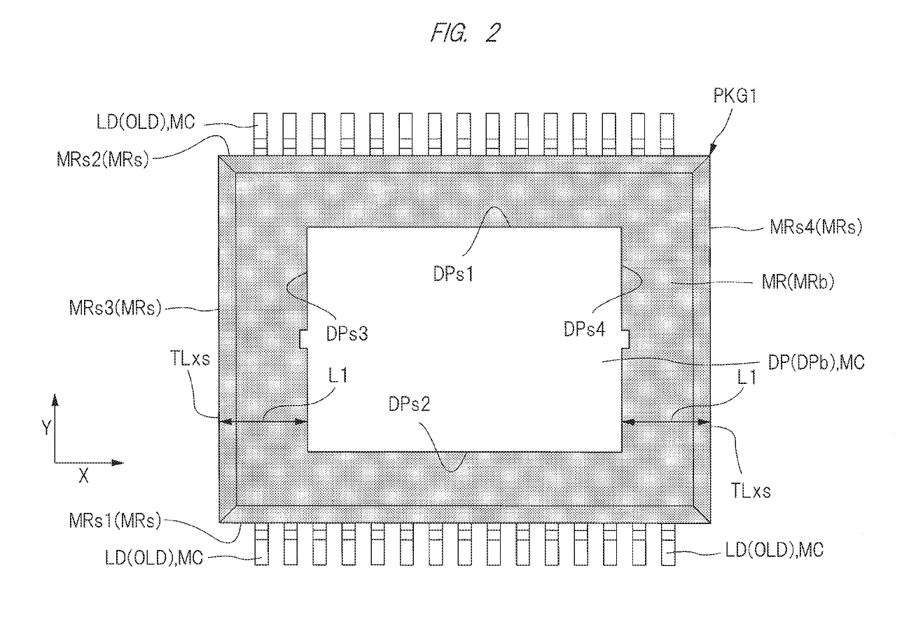

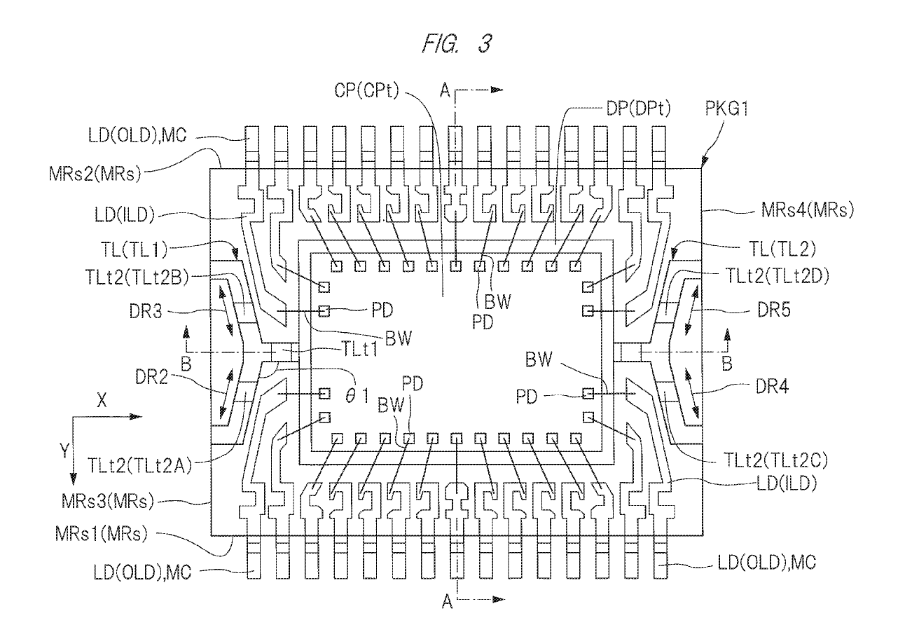

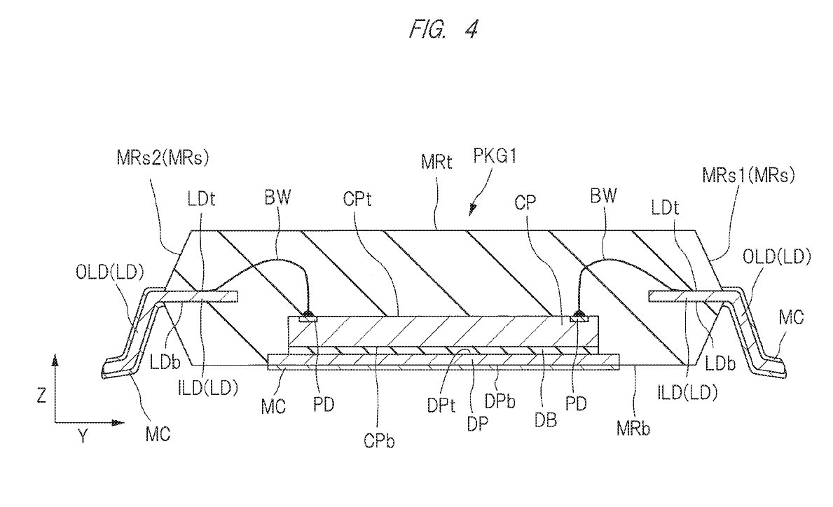

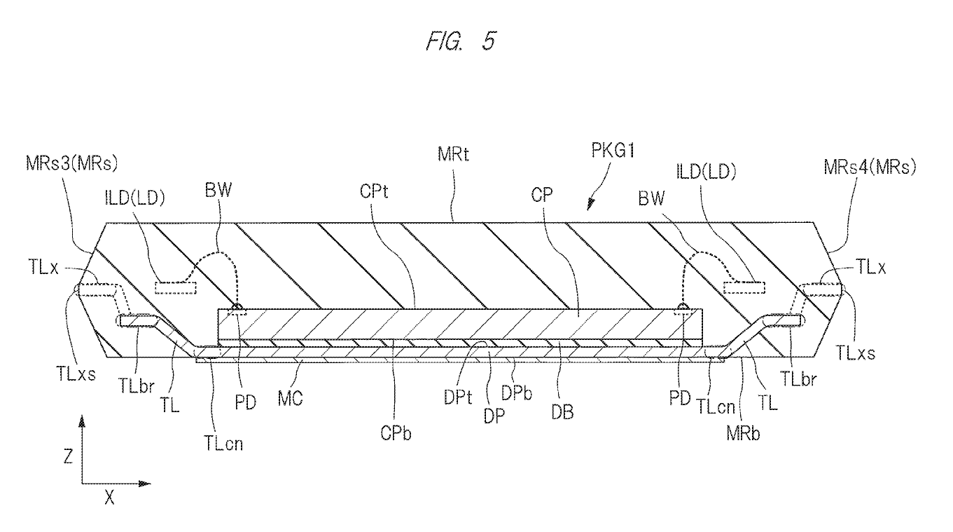

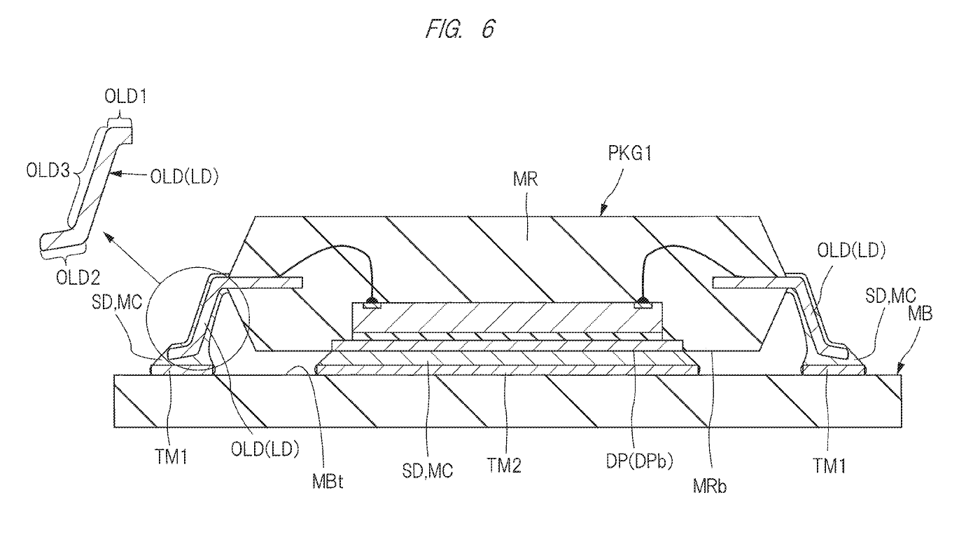

First, the outline of the configuration of a semiconductor device PKG1 of the present embodiment will be described with reference to FIGS. 1 to 6. FIG. 1 is a perspective view of a semiconductor device of the present embodiment. FIG. 2 is a bottom view of the semiconductor device shown in FIG. 1. Also, FIG. 3 is a plan view showing an internal structure of the semiconductor device in a state where the sealing body shown in FIG. 1 is removed. In addition, FIG. 4 is a cross-sectional view taken along line A-A of FIG. 3, and FIG. 5 is a cross-sectional view taken along line B-B of FIG. 3. Further, FIG. 6 is a cross-sectional view showing a mounting structure in which the semiconductor device shown in FIG. 4 is mounted on a mounting board. In the cross section shown in FIG. 5, pads PD, leads LD, and wires BW are not provided, but are indicated by broken lines for explicitly showing the height relationship between suspension leads TL and the leads LD. Similarly, in the cross section shown in FIG. 5, an exposed-surface connection section TLx of the suspension lead TL is not provided, but in order to clearly show the difference in height between the exposed-surface connection section TLx of the suspension lead TL and a die pad DP, the exposed-surface connection sections TLx are indicated by broken lines.

The semiconductor device PKG1 of the present embodiment includes the die pad (chip mounting section, tab) DP (see FIGS. 2 to 5) and a semiconductor chip CP (see FIGS. 3 to 5) mounted on the die pad DP via a die bonding material DB (see FIGS. 4 and 5). In addition, the semiconductor device PKG1 has a plurality of leads (terminals, external terminals) LD arranged around the semiconductor chip CP (die pad DP). The plurality of leads LD and the plurality of pads (electrodes, bonding pads) PD (see FIGS. 3 and 4) of the semiconductor chip CP are electrically connected to each other via the plurality of wires (conductive members) BW (see FIGS. 4 and 5). Also, the plurality of suspension leads TL (see FIGS. 3 and 5) are connected to the die pad DP. In addition, the semiconductor device PKG1 includes a sealing body (resin body) MR that seals the semiconductor chip CP, the plurality of wires BW, and a part of the plurality of leads LD.

<External Structure>

The external structure of the semiconductor device PKG1 will be described. The sealing body (resin body) MR shown in FIG. 1 has a quadrangular planar shape (rectangular shape in the example shown in FIG. 1). The sealing body MR has an upper surface (sealing body upper surface) MRt, a lower surface (back surface, mounting surface, sealing body lower surface) MRb (see FIG. 2) opposite to the upper surface MRt and side surfaces (sealing body side surfaces) MRs positioned between the upper surface MRt and the lower surface MRb.

In addition, as shown in FIG. 2, the sealing body MR has a long side (side) MRs1 extending in an X direction, a long side (side) MRs2 positioned opposite to the long side MRs1, a short side (side) MRs3 extending in a Y direction intersecting the X direction and a short side (side) MRs4 positioned opposite to the short side MRs3 in plan view. Further, the die pad DP has a long side (side) DPs1 extending in the X direction, a long side (side) DPs2 positioned opposite to the long side DPs1, a short side (side) DPs3 extending in the Y direction intersecting the X direction, and a short side (side) DPs4 positioned opposite to the short side DPs3 in plan view.

In addition, the sealing body MR of the present embodiment has a rectangular planar shape, and the plurality of leads LD are arranged along the long sides MRs1 and MRs2 respectively among the four sides of the sealing body MR. In other words, the plurality of leads LD protrude from the long sides MRs1 and MRs2 respectively among the four sides of the sealing body MR.

Further, the die pad DP of the present embodiment has a rectangular planar shape, and the plurality of leads LD are arranged along the long sides DPs1 and DPs2 respectively among the four sides of the die pad DP.

On the other hand, the leads LD are not arranged on the short sides MRs3 and MRs4 of the sealing body MR. In other words, no leads LD protrude from the short sides MRs3 and MRs4 of the sealing body MR.

The semiconductor package in which a plurality of leads are arranged along the long sides positioned opposite to each other as described above is referred to as a SOP (Small Outline Package) type semiconductor device. Although not shown, a semiconductor device in which the plurality of leads LD protrude along the four sides of the sealing body MR respectively is referred to as a QFP (Quad Flat Package). As in the present embodiment, since the leads are not provided on the short sides of the sealing body MR in the SOP type semiconductor device, the function of reducing the stress generated when or after the semiconductor device PKG1 is mounted on a mounting board MB shown in FIG. 6 is superior to that of the QFP type semiconductor device. On the other hand, since each of the four sides of the sealing body can be utilized as an arrangement space for the leads LD in the case of a QFP type semiconductor device, the arrangement density of the terminals can be improved as compared with the SOP type semiconductor device.

Although details will be described later, the leads LD are not arranged on the short side DPs3 and the short side DPs4 of the die pad DP in the example shown in FIG. 2. However, as shown in FIG. 3, some of the leads LD arranged on the long sides DPs1 and DPs2 (see FIG. 2) of the die pad DP extend so as to curve around toward the short sides DPs3 and DPs4 of the die pad DP (see FIG. 2) inside the sealing body MR.

In addition, as shown in FIG. 2, a lower surface DPb of the die pad DP is exposed at the center of the lower surface (mounting surface) MRb of the semiconductor device PKG1. By exposing the lower surface DPb of the die pad DP on which the semiconductor chip CP (see FIG. 3) is mounted, on the mounting surface in this way, the heat dissipation performance when the semiconductor device PKG1 is mounted on the mounting board MB shown in FIG. 6 can be improved.

Further, each of the plurality of leads LD is made of a metal material, and is made of, for example, metal containing copper (Cu) as a main component in the present embodiment. Also, the thickness of each of the plurality of leads LD is not particularly limited, and is, for example, about 150 μm in the example shown in FIG. 1. In addition, each of the plurality of leads LD is provided with an inner lead section ILD (see FIGS. 3 and 4) sealed in the sealing body MR and an outer lead section OLD exposed from the sealing body MR.

Further, as shown in FIGS. 1 and 4, the surface (exposed surface, disclosed surface) of the outer lead section OLD of the lead LD and the lower surface DPb of the die pad DP are covered with a metal film (metal coating film) MC. The metal film MC is, for example, a plating film formed by a plating method, more specifically, an electrolytic plating film formed by an electrolytic plating method. Further, the metal film MC is made of, for example, a solder material, and functions as a part of a bonding material SD when the lead LD is bonded to a terminal TM1 on the mounting board MB shown in FIG. 6. To be specific, the metal film MC is made of so-called lead-free solder which contains substantially no lead (Pb), and is a metal material containing tin as a main component such as pure tin (Sn), tin-bismuth (Sn—Bi) or tin-copper-silver (Sn—Cu—Ag). Here, the lead-free solder means a solder whose content of lead (Pb) is 0.1 wt % or less, and this content is defined as a standard of the RoHS (Restriction of Hazardous Substances) directive. Hereinafter, in the present embodiment, when a solder material or a solder component is described, it indicates lead-free solder unless otherwise specified.

Further, each of the outer lead sections OLD (portions exposed from the sealing body MR) of the plurality of leads LD has a portion (protruding section OLD1) protruding from the central portion of the side surface MRs of the sealing body MR as shown in FIG. 6. In addition, the outer lead section OLD has a portion (mounted section OLD2) arranged to face the terminal TM1 of the mounting board MB at the time of mounting. Further, the outer lead section OLD has a portion (inclined section OLD3) provided between the protruding section OLD1 and the mounted section OLD2 and inclined with respect to the mounting surface (lower surface MRb) of the semiconductor device PKG1.

In the case where a temperature cycle load is applied to the semiconductor device PKG1 and the mounting board MB in a state where the mounted section OLD2 is fixed to the terminal TM1 as shown in FIG. 6, the stress applied to the connection section between the lead LD and the terminal TM1 can be reduced if the inclined section OLD3 is elastically deformed. In this way, from the viewpoint of improving the stress reduction function of the inclined section OLD3, the inclined section OLD3 with the longer length is better.

Further, when the length of the inclined section OLD3 shown in FIG. 6 is increased, the volume of the sealing body MR increases. When the volume of the sealing body MR increases in this manner, the heat dissipation performance of the package can be improved.

In the example shown in FIG. 6, the length of the inclined section OLD3 of the lead LD is larger than half (e.g., 1.3 mm) of the thickness (e.g., 2.6 mm) of the sealing body MR. On the other hand, the thickness of the semiconductor chip CP is about 400 μm, and the length of the inclined section OLD3 of the lead LD is larger than the thickness of the semiconductor chip CP.

<Internal Structure>

Next, the internal structure of the semiconductor device PKG1 will be described. As shown in FIG. 3, an upper surface (chip mounting surface) DPt of the die pad DP has a quadrangular (quadrilateral) planar shape. In the present embodiment, for example, it has a rectangular shape. Also, in the example shown in FIG. 3, the external size (area) of the die pad DP is larger than the external size (area of a front surface CPt) of the semiconductor chip CP. By mounting the semiconductor chip CP on the die pad DP having an area larger than the external size of the semiconductor chip CP and exposing the lower surface DPb of the die pad DP from the sealing body MR, heat dissipation performance can be improved.

In addition, the semiconductor chip CP is mounted on the die pad DP as shown in FIGS. 3 to 5. The semiconductor chip CP is mounted at the center of the upper surface DPt of the die pad DP. As shown in FIG. 5, the semiconductor chip CP is mounted on the die pad DP via the die bonding material (adhesive material) DB (see FIG. 4) in a state where a back surface CPb faces the upper surface DPt of the die pad DP. Namely, the semiconductor chip CP is mounted by a so-called face-up mounting method in which the surface (back surface CPb) opposite to the front surface (main surface) CPt on which the plurality of pads PD are formed is made to face the chip mounting surface (upper surface DPt). The die bonding material DB is an adhesive material for use in the die bonding of the semiconductor chip CP. As the die bonding material DB, for example, a resin adhesive material, a conductive adhesive material made of a resin adhesive material containing metal particles of silver (Ag) or the like or a solder material can be used. When a solder material is used as the die bonding material DB, a solder material containing lead may be used for the purpose of raising the melting point.

As shown in FIG. 3, the semiconductor chip CP mounted on the die pad DP has a quadrangular planar shape. In the present embodiment, for example, it has a rectangular shape. In addition, as shown in FIG. 4, the semiconductor chip CP has the front surface (main surface, upper surface) CPt, the back surface (main surface, lower surface) CPb opposite to the front surface CPt, and side surfaces CPs positioned between the front surface CPt and the back surface CPb. Also, the plurality of pads (bonding pads) PD are formed on the front surface CPt of the semiconductor chip CP as shown in FIG. 3. In the example shown in FIG. 3, the plurality of pads PD are formed along each side of the front surface CPt. In other words, the plurality of pads PD are arranged along each of the long sides located opposite to each other. Further, the plurality of pads PD are arranged along each of the short sides located opposite to each other.

Although not shown, a plurality of semiconductor elements (circuit elements) are formed on the main surface of the semiconductor chip CP (more specifically, in the semiconductor element formation region provided on the upper surface of the base member (semiconductor substrate) of the semiconductor chip CP). In addition, the plurality of pads PD are electrically connected to the semiconductor elements via wirings (not shown) formed in the wiring layer disposed inside the semiconductor chip CP (more specifically, between the front surface CPt and the semiconductor element formation region (not shown)).

The semiconductor chip CP (more specifically, the base member of the semiconductor chip CP) is made of, for example, silicon (Si). Also, an insulating film which covers the base member of the semiconductor chip CP and the wiring is formed on the front surface CPt, and the surface of each of the plurality of pads PD is exposed from the insulating film at an opening formed in the insulating film. In addition, the pad PD is made of metal, for example, aluminum (Al) or an alloy layer containing aluminum (Al) as a main component in the present embodiment.

Although not shown, as a modification example to the present embodiment, a so-called power semiconductor chip may be mounted on the die pad DP. The power semiconductor chip has transistor elements such as an insulated gate bipolar transistor (IGBT) or a power MOSFET (Metal Oxide Semiconductor Field Effect Transistor). Further, the power semiconductor chip is incorporated in a power conversion circuit or the like and operates as, for example, a switching element. In addition, for example, a source electrode pad is formed on the front surface of the power semiconductor chip, and a drain electrode pad is formed on the back surface. In that case, the drain electrode pad is electrically connected to the die pad DP via the die bonding material DB, and the die pad DP is used as a drain terminal.

Further, as shown in FIG. 3, for example, the plurality of leads LD made of copper (Cu) similarly to the die pad DP are disposed around the semiconductor chip CP (in other words, around the die pad DP). Further, the plurality of pads (bonding pads) PD formed on the front surface CPt of the semiconductor chip CP are electrically connected to the plurality of leads LD via a plurality of wires (conductive members) BW, respectively. The wire BW is made of, for example, gold (Au) or copper (Cu), and one end of the wire BW is bonded to the pad PD and the other end is bonded to the bonding region of an upper surface LDt of the lead LD. Although not shown, a metal film (plating, plating film) made of silver (Ag) or the like for improving the bonding property with the wire BW may be formed in the bonding region of the lead LD (part to which the wire BW is connected).

Also, as shown in FIG. 4, the lead LD has the upper surface (wire bonding surface, lead upper surface) LDt sealed in the sealing body MR and a lower surface (mounting surface, lead lower surface) LDb located opposite to the upper surface LDt and exposed from the sealing body MR on the lower surface MRb of the sealing body MR.

In addition, as shown in FIG. 3, a plurality of suspension leads TL are connected (coupled) to the die pad DP. Each of the plurality of suspension leads TL is a support member for supporting the die pad DP during the manufacturing process of the semiconductor device PKG1, and is connected to the die pad DP. In the example shown in FIG. 3, one ends of the plurality of suspension leads TL are connected respectively to the short sides DPs3 (see FIG. 2) and DPs4 (see FIG. 2) located opposite to each other among the four sides of the die pad DP having a rectangular shape in plan view.

Further, as shown in FIG. 5, each of the plurality of suspension leads TL is bent at a plurality of locations between a tab connection section (part) TLcn connected with the die pad DP and an exposed surface TLxs exposed from the sealing body MR. Further, most of the suspension leads TL are sealed in the sealing body MR. The detailed structure of the suspension lead TL will be described later.

<Detailed Structure of Suspension Lead>

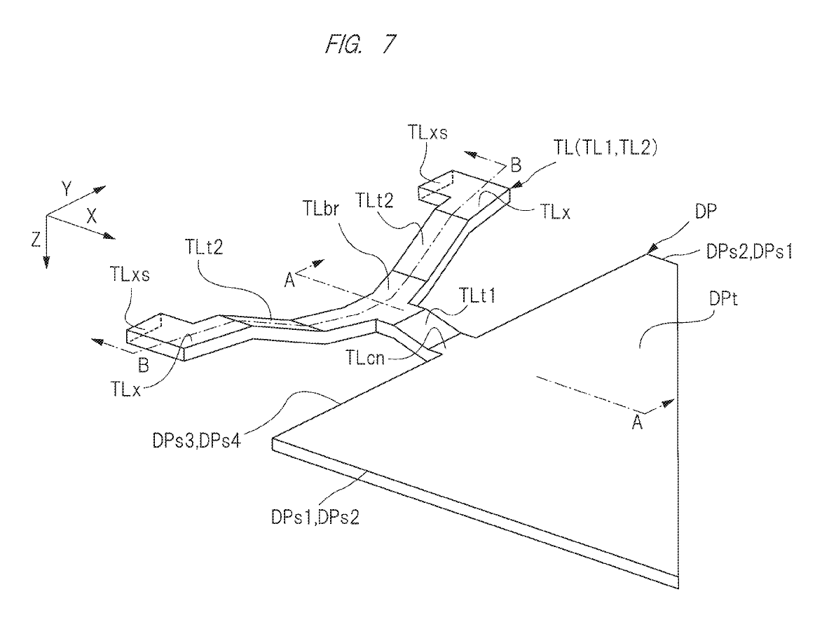

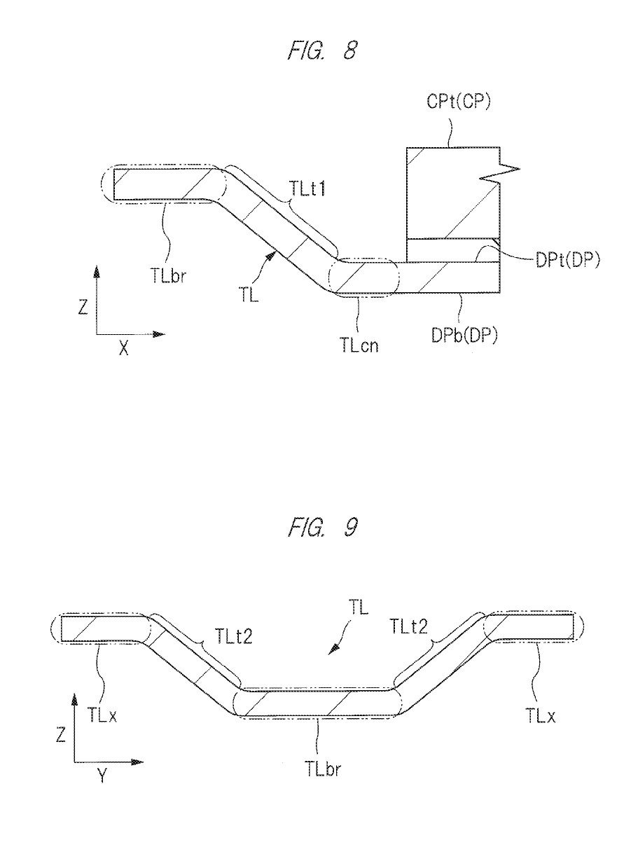

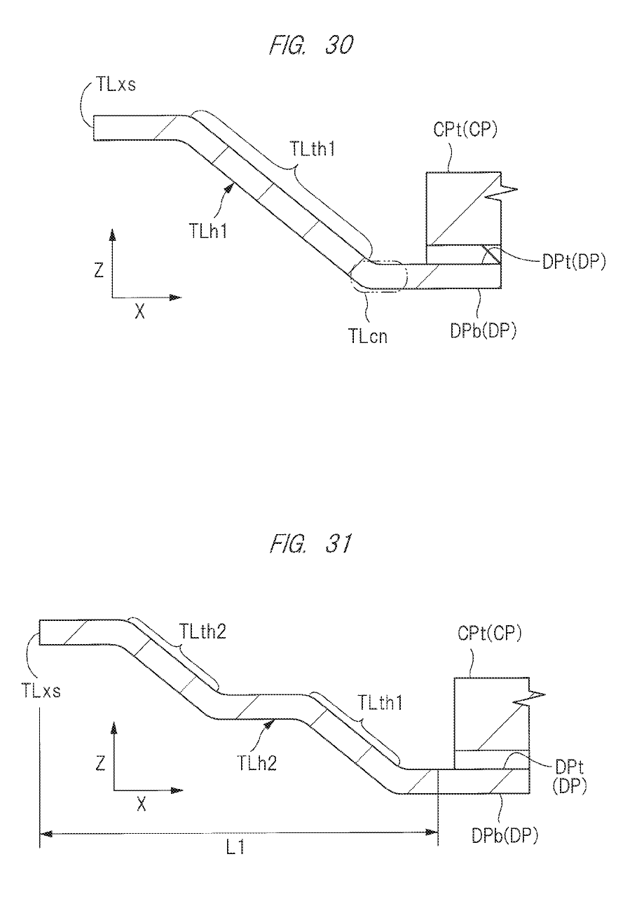

Next, the structure of the suspension leads shown in FIGS. 3 and 5 will be described. FIG. 7 is an enlarged perspective view showing one of the two suspension leads shown in FIG. 3 in an enlarged manner. Also, FIG. 8 is an enlarged cross-sectional view taken along line A-A of FIG. 7, and FIG. 9 is an enlarged cross-sectional view taken along line B-B of FIG. 7. Further, FIGS. 30 and 31 are enlarged cross-sectional views showing examination examples of the suspension leads shown in FIGS. 8 and 9.

In the case of the present embodiment, as shown in FIG. 3, a suspension lead TL1 provided on the short side MRs3 of the sealing body MR and a suspension lead TL2 provided on the short side MRs4 form a line symmetrical structure. Therefore, although FIGS. 7 to 9 show one suspension lead TL, the structures of the suspension lead TL1 and the suspension lead TL2 shown in FIG. 3 are the same as the structure of the suspension lead TL shown in FIGS. 7 to 9. Further, FIGS. 8, 30 and 31 show the semiconductor chip CP mounted on the die pad DP as a comparison reference so that the length and the height of the suspension lead can be easily compared.

As shown in FIG. 7, the suspension lead TL has the tab connection section TLcn connected to the die pad DP and extending in the X direction. Further, the suspension lead TL has a branch section TLbr provided at a position higher than the tab connection section TLcn with respect to the upper surface DPt serving as the chip mounting surface and branching in a plurality of directions intersecting the X direction. In the example shown in FIG. 7, the branch section TLbr branches in two directions intersecting the X direction. In other words, in the example shown in FIG. 7, the suspension lead TL is divided into three branches at the branch section TLbr because one offset section TLt1 and two offset sections TLt2 are connected thereto. In addition, the suspension lead TL has a plurality of exposed-surface connection sections TLx provided at positions higher than the branch section TLbr and each having one end connected to the exposed surface TLxs exposed from the sealing body MR (see FIG. 3) on the short side MRs.

In addition, the suspension lead TL has the offset section (inclined section) TLt1 connected to the tab connection section TLcn and the branch section TLbr and the plurality of offset sections TLt2 each having one end connected to the branch section TLbr and the other end connected to each of the plurality of exposed-surface connection sections TLx.

In the example shown in FIG. 3, the suspension lead TL1 has the offset section TLt1 extending in the X direction which is the first direction, an offset section TLt2A extending in a second direction DR2 intersecting the X direction, and an offset section TLt2B extending in a third direction DR3 intersecting the X direction in plan view.

Further, in the example shown in FIG. 3, the suspension lead TL2 forms a line symmetrical structure with the suspension lead TL1. Namely, the suspension lead TL2 has the offset section TLt1 extending in the X direction which is the first direction, an offset section TLt2C extending in a fourth direction DR4 intersecting the X direction, and an offset section TLt2D extending in a fifth direction DR5 intersecting the X direction in plan view.

As shown in FIG. 6 mentioned above, from the viewpoint of reducing the stress applied to the semiconductor device PKG1 and improving the mounting reliability, the inclined section OLD3 with the longer length is better. However, in order to lengthen the inclined section OLD3 and expose the lower surface DPb of the die pad DP from the sealing body MR, the height difference between the exposed surface TLxs of the suspension lead TL and the die pad DP shown in FIG. 7 is increased. For example, the height difference between the upper surface of the exposed-surface connection section TLx and the upper surface DPt of the die pad DP shown in FIG. 7 is about 1.3 mm. Also, as shown in FIG. 4, in the semiconductor device PKG1 of the present embodiment, each of the plurality of pads PD of the semiconductor chip CP is provided at a position lower than the inner lead sections ILD of the plurality of leads LD with respect to the die pad DP. The inner lead sections ILD of the leads LD are provided at the same height as the exposed-surface connection section TLx shown in FIG. 7. Accordingly, it is understood also from this point that the semiconductor device PKG1 of the present embodiment has a large difference in height between the exposed surface TLxs of the suspension lead TL and the die pad DP shown in FIG. 7.

When the height difference between the exposed surface TLxs of the suspension lead TL and the die pad DP is large as described above, the length of the inclined section (offset section) of the suspension lead TL for connecting the exposed surface TLxs and the die pad DP increases.

Here, when only one offset section TLth1 is provided between the exposed surface TLxs and the die pad DP as in a suspension lead TLh1 shown in FIG. 30, the offset section TLth1 is likely to deform due to the long length of the offset section TLth1, and support strength for supporting the die pad DP decreases. Hence, from the viewpoint of improving the support strength for supporting the die pad DP, a plurality of offset sections are preferably provided between the exposed surface TLxs and the die pad DP.

Also, when the offset section TLth1 and an offset section TLth2 are arranged to extend linearly in the X direction between the exposed surface TLxs and the die pad DP as in a suspension lead TLh2 shown in FIG. 31, a planar distance L1 from the exposed surface TLxs to the die pad DP increases. In this case, the mounting area of the semiconductor package increases.

In addition, as a method of shortening the planar distance L1 from the exposed surface TLxs to the die pad DP, the offset sections TLth1 and TLth2 may be configured to have larger inclination angles. However, if the bending angles of the bent portions of the offset sections TLth1 and TLth2 increase, the thickness of the bent portion tends to become thin, and the strength of the suspension lead decreases. Accordingly, from the viewpoint of improving the strength of the suspension lead, the inclination angles of the offset sections TLth1 and TLth2 are preferably small.

On the other hand, the suspension lead TL of the present embodiment has the offset sections TLt1 and TLt2 between the exposed surface TLxs and the die pad DP as shown in FIG. 7. Thus, since the suspension lead TL is hard to deform as compared with the suspension lead TLh1 shown in FIG. 30, the support strength for the die pad DP can be improved.

Further, each of the plurality of offset sections TLt2 in the suspension lead TL shown in FIG. 7 extends in a direction intersecting the X direction. Therefore, in the suspension lead TL according to the present embodiment, the planar distance L1 from the exposed surface TLxs to the die pad DP (see FIG. 2) can be shortened as compared with the examination example shown in FIG. 31. As a result, the mounting area of the semiconductor device PKG1 (see FIG. 2) can be reduced.

Note that there are various modification examples of the angle formed by the direction in which each of the plurality of offset sections TLt2 extends and the X direction. For example, as shown in FIG. 3, the angle θ1 between the extending direction of the offset section TLt2 and the X direction may be an obtuse angle greater than 90 degrees. In this case, since a space for providing the lead LD can be secured between the offset section TLt2 of the suspension lead TL1 and the die pad DP in plan view, the number of the leads LD can be increased. Further, for example, the angle formed by the extending direction of the offset section TLt2 and the X direction may be 90 degrees or less. In this case, the planar distance L1 (see FIG. 2) from the exposed surface TLxs to the die pad DP can be particularly reduced.

Note that, in the present embodiment, the suspension leads TL1 and TL2 shown in FIG. 3 have similar structures. Therefore, as shown in FIG. 2, both of the planar distance L1 from the short side DPs3 of the die pad DP to the exposed surface TLxs and the planar distance L1 from the short side DPs4 of the die pad DP to the exposed surface TLxs can be reduced on the back surface MRb of the sealing body MR. As a modification example to FIG. 3, if the structure shown in FIG. 7 is applied to either one of the suspension lead TL1 and the suspension lead TL2 shown in FIG. 3, the mounting area of the semiconductor package can be reduced even when the other suspension lead TL has the structure like the suspension lead TLh2 shown in FIG. 31. However, needless to say, the effect of reducing the mounting area is greater when the suspension leads TL1 and TL2 have similar structures like in the present embodiment. In addition, when the suspension leads TL1 and TL2 have an asymmetric structure, stress may concentrate at a part of the suspension leads TL1 and TL2. Accordingly, from the viewpoint of improving the support strength for the die pad DP by the suspension lead TL, the suspension leads TL1 and TL2 preferably form a line symmetrical structure as shown in FIG. 3.

Further, in the suspension lead TL of the present embodiment, the extending directions of the offset sections TLt1 and TLt2 are different from each other, and thus the inclination angles of the offset sections TLt1 and TLt2 can be reduced. The inclination angle of each of the offset section TLt1 and the plurality of offset sections TLt2 shown in FIG. 7 with respect to the upper surface DPt of the die pad DP which is a chip mounting surface is less than 45 degrees. When the inclination angles of the offset section TLt1 and the plurality of offset sections TLt2 are less than 45 degrees, the reduction of the plate thickness of the bent portion formed at both ends of the offset section can be suppressed. As a result, the strength of the suspension lead TL can be improved.

Also, as shown in FIG. 7, the tab connection section TLcn of the suspension lead TL1 is connected to the center of the short side DPs3 of the die pad DP in plan view. Similarly, the tab connection section TLcn of the suspension lead TL2 is connected to the center of the short side DPs4 of the die pad DP. By connecting the tab connection sections TLcn to the centers of the short sides DPs3 and DPs4 in this manner, spaces can be secured on both sides of the tab connection sections TLcn. In the example shown in FIG. 3, some of the plurality of inner lead sections ILD are provided so as to curve around from the long sides MRs1 and MRs2 to the spaces on both sides of the offset sections TLt1.

To be more specific, as shown in FIG. 3, the plurality of outer lead sections OLD are arranged along the long sides MRs1 and MRs2 of the sealing body MR, and are not arranged along the short sides MRs3 and MRs4 of the sealing body MR. Also, the plurality of inner lead sections ILD are formed along the long side DPs1 (see FIG. 7), the long side DPs2 (see FIG. 7), the short side DPs3 (see FIG. 7), and the short side DPs4 (see FIG. 7) of the die pad DP.

In other words, the semiconductor device PKG1 of the present embodiment is a SOP type semiconductor device in which the plurality of leads LD are arranged along the long sides MRs1 and MRs2 of the sealing body MR. However, inside the sealing body MR, some of the plurality of inner lead sections ILD are formed so as to curve around toward the short sides MRs3 and MRs4 of the sealing body MR. Therefore, the plurality of pads PD are arranged along each of the four sides of the semiconductor chip CP having a quadrangular shape in plan view. In addition, some of the plurality of wires BW that electrically connect the plurality of pads PD of the semiconductor chip CP and the plurality of inner lead sections ILD are configured to pass over the short sides DPs3 and DPs4 (see FIG. 7) of the die pad DP.

According to the present embodiment, the arrangement density of the leads LD can be improved by utilizing the region provided on the short side of the die pad DP as the arrangement space for the inner lead section ILD as described above.

<Mounting Method of Semiconductor Device>

Next, an example of a method of mounting the semiconductor device PKG1 on the mounting board MB will be described with reference to FIG. 6.

In the method of mounting the semiconductor device described in the present embodiment, the mounting board MB is first prepared (board preparation process). The mounting board (mother board, wiring board) MB has an upper surface (mounting surface) MBt as an electronic component mounting surface, and the semiconductor device PKG1 described with reference to FIGS. 1 to 9 is mounted on the upper surface MBt. A plurality of terminals which are terminals on the mounting board side are arranged on the upper surface MBt. In the example shown in FIG. 6, the mounting board MB is provided with a plurality of terminals (lead connection terminals, lands) TM1 and a terminal (die pad connection terminal, land) TM2.

Next, a bonding material (not shown) is disposed on (applied to) the plurality of terminals TM1 and TM2 provided on the upper surface MBt of the mounting board MB (bonding material disposition process). The bonding material is a solder material referred to as cream solder (or paste solder). The cream solder contains a solder component serving as a conductive bonding material and a flux component for activating the surface of the bonding portion, and is in a paste form at room temperature.

In the present embodiment, as shown in FIG. 2, each of the plurality of leads LD and the die pad DP is exposed on the lower surface MRb of the sealing body MR in the semiconductor device PKG1, and these are respectively connected to the terminals TM1 and TM2 of the mounting board MB. Hence, in this process, a bonding material is applied to each of the plurality of terminals TM1 and TM2.

Next, the semiconductor device PKG1 is placed on the upper surface MBt of the mounting board MB (package mount process). In this process, the positions of the mounted sections OLD2 of the plurality of leads LD of the semiconductor device PKG1 and the positions of the terminals TM1 on the mounting board MB are aligned so as to overlap with each other, and the semiconductor device PKG1 is arranged on the upper surface MBt that is the mounting surface of the mounting board MB. Further, in this process, the semiconductor device PKG1 is arranged so that the die pad DP overlaps with the terminal TM2.

Next, heat treatment is performed in a state where the semiconductor device PKG1 is disposed on the mounting board MB, and the plurality of leads LD and the plurality of lands LNDa are bonded respectively via the bonding material SD (reflow process) as shown in FIG. 6. The bonding material SD shown in FIG. 6 is a conductive member (solder material) formed by integrating a solder component contained in the above-described solder material and a solder component of the metal film MC. Also, one surface of the bonding material SD is bonded to the mounted section OLD2 of the lead LD, and the other surface of the bonding material SD is bonded to the exposed surface of the terminal TM1. In other words, in this process, the plurality of leads LD and the plurality of terminals TM1 are electrically connected to each other respectively via the bonding material SD.

Further, on the terminal TM2 which is the terminal for connecting the die pad, one surface of the bonding material SD is bonded to the lower surface DPb of the die pad DP, and the other surface of the bonding material SD is bonded to the exposed surface of the terminal TM2. Namely, in this process, a heat dissipation path connected between the die pad DP and the mounting board MB is formed. Further, when the die pad DP is used as, for example, a terminal for supplying reference potential, the die pad DP and the terminal TM2 are electrically connected to each other via the bonding material SD in this process.

Here, the mounting strength of the semiconductor device PKG1 will be described. After the semiconductor device PKG1 is mounted on the mounting board MB, a temperature cycle load is applied in the usage environment. The temperature cycle load is a load caused by repeatedly changing the environmental temperature of the mounting structure in which the semiconductor device PKG1 is mounted on the mounting board MB. The temperature cycle load includes, for example, a stress generated due to a difference in a linear expansion coefficient of each member constituting the mounting structure. This stress tends to concentrate at the periphery of the mounting surface of the semiconductor device PKG1. For this reason, in order to prolong the temperature cycle life (the number of temperature cycles before the connection section is damaged by the temperature cycle load), it is preferable to reduce the concentration of stress to the vicinity of the connection section between the lead LD and the terminal TM1 arranged at the periphery of the mounting surface.

As described above, in order to lengthen the inclined section OLDS of the lead LD in the semiconductor device PKG1 of the present embodiment, the height difference between the protruding section OLD1 and the mounted section OLD2 is as large as about 1.3 mm to 1.4 mm. As a package type intended to reduce the thickness of the semiconductor package, there is a package referred to as TSOP (Thin Small Outline Package) in addition to the SOP type of the present embodiment. In this TSOP type semiconductor package, the thickness reduction can be achieved by reducing the length of the inclined section OLD3 of the lead LD, and the height difference between the protruding section OLD1 and the mounted section OLD2 is, for example, about 0.5 mm to 0.6 mm.

If the length of the inclined section OLD3 of the lead LD is increased as in the present embodiment, the stress generated due to the temperature cycle load can be reduced by the elastic deformation of the inclined section OLD3. Hence, the mounting reliability can be improved in the semiconductor device PKG1 of the present embodiment as compared with the TSOP type semiconductor device.

Also, the semiconductor device PKG1 of the present embodiment is a SOP type semiconductor device in which the leads LD are not arranged on the short side of the sealing body MR. In this case, when stress is applied to the mounted semiconductor device PKG1, the semiconductor device PKG1 is easily deformed elastically in the X direction shown in FIG. 2 as compared with the QFP type semiconductor device. As a result, the mounting reliability can be improved in the SOP type semiconductor device PKG1 as compared with the QFP type semiconductor device.

<Manufacturing Method of Semiconductor Device>

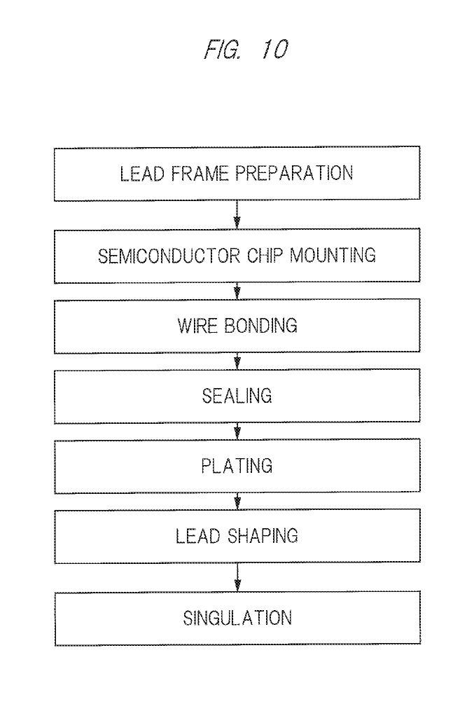

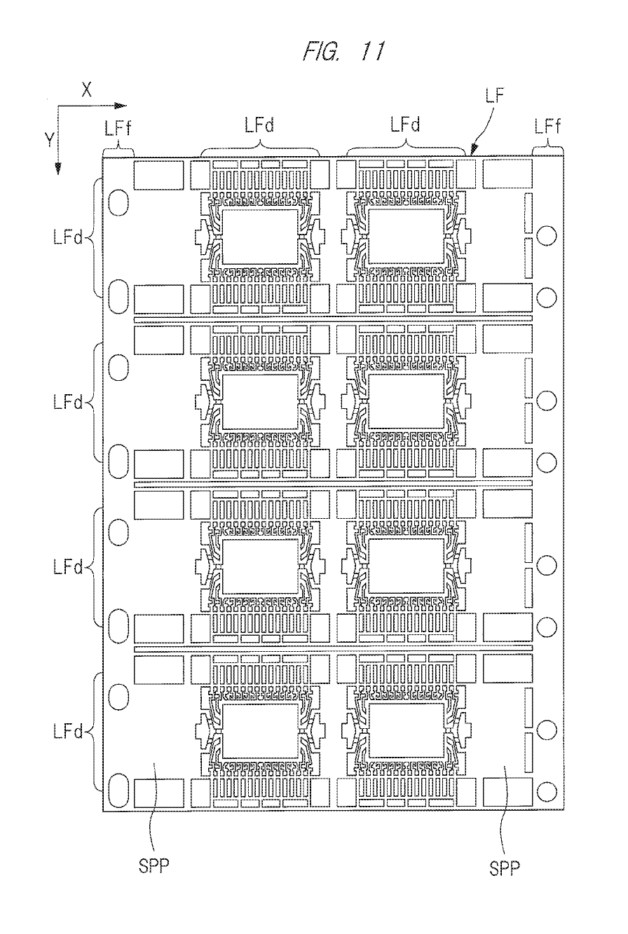

Next, a manufacturing method of the semiconductor device PKG1 shown in FIGS. 1 to 9 will be described. The semiconductor device PKG1 in the present embodiment is manufactured along the assembly flow shown in FIG. 10. FIG. 10 is an explanatory diagram showing the assembly flow of the semiconductor device shown in FIG. 1.

1. Lead Frame Preparation Process:

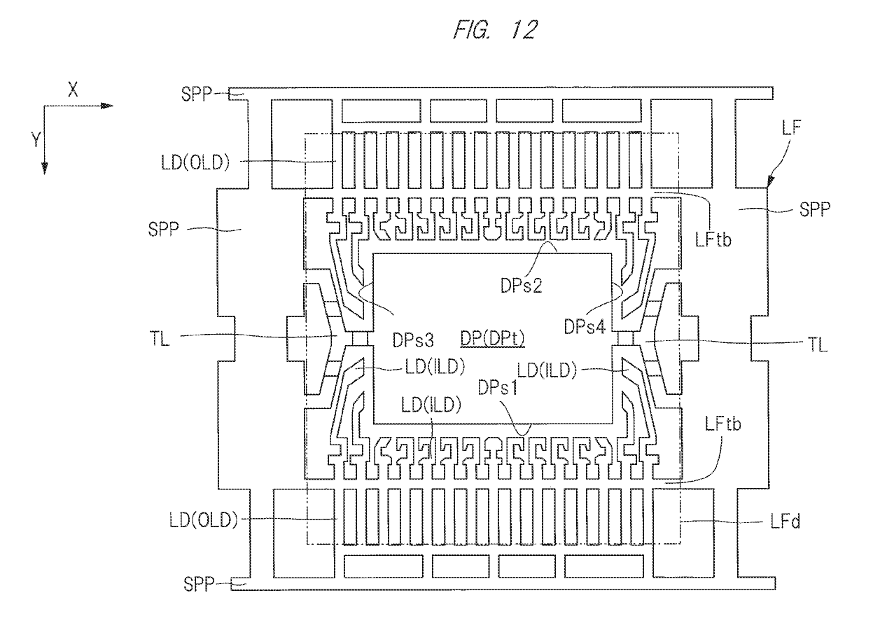

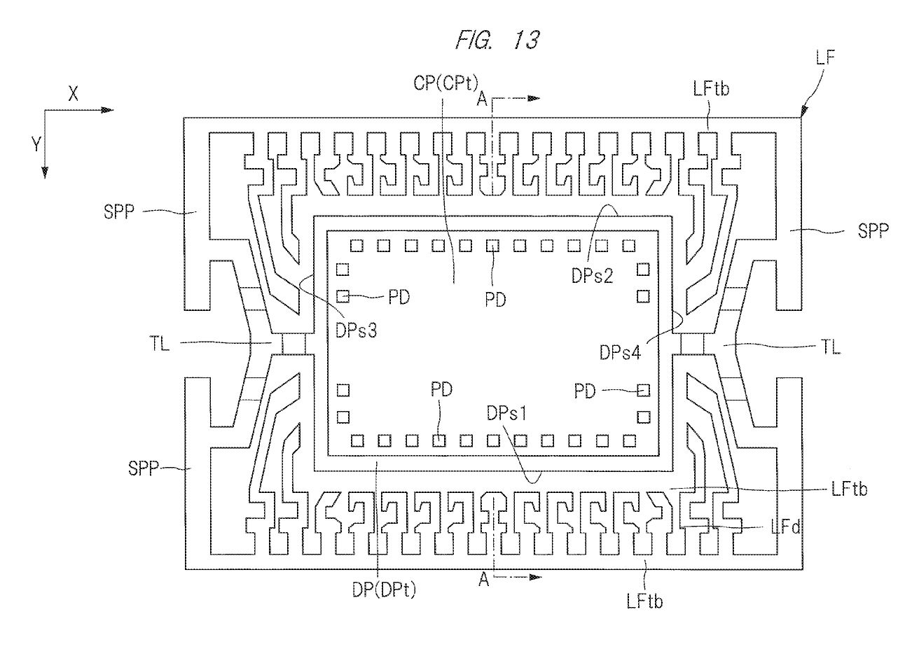

First, as a lead frame preparation process shown in FIG. 10, a lead frame LF as shown in FIG. 11 is prepared. FIG. 11 is a plan view showing the entire structure of the lead frame to be prepared in the lead frame preparation process of FIG. 10, and FIG. 12 is an enlarged plan view of the periphery of one device region among a plurality of device regions shown in FIG. 11.

The lead frame LF to be prepared in this process has a plurality of device regions (product formation regions) LFd inside an outer frame LFf. In the example shown in FIG. 11, the lead frame LF has two device regions LFd in the X direction and four device regions LFd in the Y direction arranged in a matrix form, that is, a total of eight device regions LFd. The lead frame LF is made of metal, for example, copper (Cu) or a layered metal film in which a metal film (not shown) made of nickel (Ni) or the like is formed on a surface of a base member made of copper (Cu) in the present embodiment.

In addition, each of the plurality of device regions LFd is connected to the outer frames LFf via support members SPP surrounding the periphery of the device regions LFd. The support members SPP around the device regions LFd are metal members integrally formed of the same metal material as the plurality of leads LD (see FIG. 12), the die pad DP (see FIG. 12) and the outer frames LFf. The support members SPP are cut off in the singulation process shown in FIG. 10 and separated from the device regions LFd.

In addition, as shown in FIG. 12, the support member SPP is formed so as to surround the periphery of the plurality of leads LD. Also, tie bars (lead coupling sections) LFtb coupled to the plurality of leads LD are arranged in the device region LFd.

As shown in FIG. 12, the die pad DP forming a quadrangle in plan view is formed in the central portion of the device region LFd. The die pad DP is supported on the outer frame LFf shown in FIG. 11 via the plurality of suspension leads TL and the support members SPP. In each of the plurality of suspension leads TL, one end thereof is connected to the die pad DP and the other end (two branched ends in the example shown in FIG. 12) is connected to the support member SPP. The plurality of suspension leads TL are formed into the shape described with reference to FIG. 7 at the time of this process, except that the exposed surfaces TLxs shown in FIG. 7 are not formed.

In addition, the plurality of leads LD are formed around the die pad DP. Each of the plurality of leads LD includes the outer lead section OLD provided outside the tie bar LFtb and the inner lead section ILD provided inside the tie bar LFtb. Each of the plurality of outer lead sections OLD is arranged in the extending direction of the long sides DPs1 and DPs2 of the die pad DP and is not arranged along the short sides DPs3 and DPs4. On the other hand, some of the plurality of inner lead sections ILD are arranged in the extending direction of the long sides DPs1 and DPs2 of the die pad DP, and the other part of the plurality of inner lead sections ILD are arranged in the extending direction of the short sides DPs3 and DPs4 of the die pad DP.

Also, the plurality of leads LD are coupled to each other via the tie bars LFtb each provided at a boundary between the outer lead section OLD and the inner lead section ILD.

2. Semiconductor Chip Mounting Process:

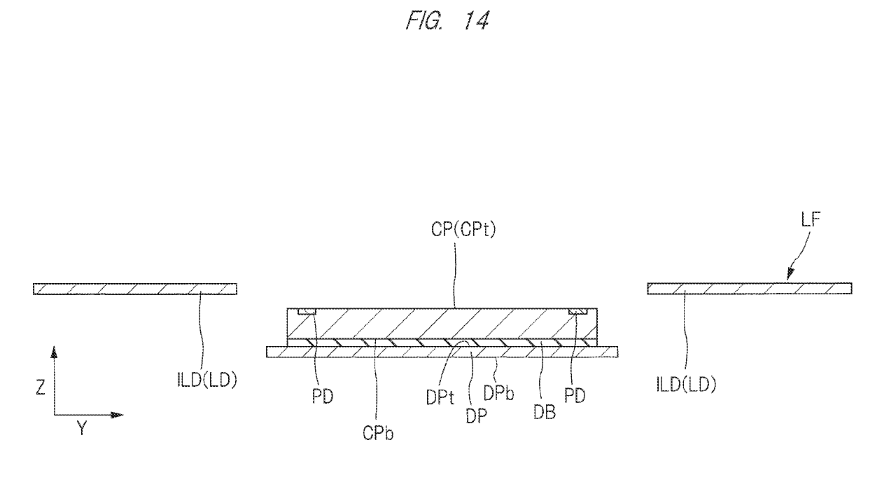

Next, as a semiconductor chip mounting process shown in FIG. 10, the semiconductor chip CP is mounted on the die pad DP via the die bonding material DB as shown in FIGS. 13 and 14. FIG. 13 is an enlarged plan view showing a state in which a semiconductor chip is mounted on the die pad shown in FIG. 12 via a bonding material, and FIG. 14 is an enlarged cross-sectional view taken along line A-A of FIG. 13. Note that, in FIG. 13, the region inside the tie bar LFtb shown in FIG. 12 is shown in an enlarged manner for ease of viewing.

In the example shown in FIG. 14, the semiconductor chip CP is mounted by a so-called face-up mounting method in which the semiconductor chip CP is mounted in a state where the back surface CPb (surface opposite to the front surface CPt on which the plurality of pads PD are formed) thereof faces the upper surface DPt of the die pad DP. Further, the semiconductor chip CP is mounted at the center of the die pad DP so that each side of the front surface CPt is arranged along each side of the die pad DP as shown in FIG. 13.

In this process, for example, the semiconductor chip CP is mounted via the die bonding material DB which is epoxy-based thermosetting resin, but the die bonding material DB is a paste material having fluidity before curing (thermosetting). When the paste material is used as the die bonding material DB in this way, the die bonding material DB is first applied onto the die pad DP, and then the back surface CPb of the semiconductor chip CP is bonded to the upper surface DPt of the die pad DP. Thereafter, by curing the die bonding material DB (for example, heating the die bonding material DB to the curing temperature) after bonding, the semiconductor chip CP is fixed on the die pad DP via the die bonding material DB as shown in FIG. 14.

Further, in this process, the semiconductor chip CP is mounted on the die pad DP provided in each of the plurality of device regions LFd (see FIG. 11) via the die bonding material DB.

Note that, in the present embodiment described above, a paste material made of thermosetting resin is used for the die bonding material DB, but various modification examples can be applied. For example, the semiconductor chip CP can be mounted via a conductive material such as solder instead of resin.

3. Wire Bonding Process:

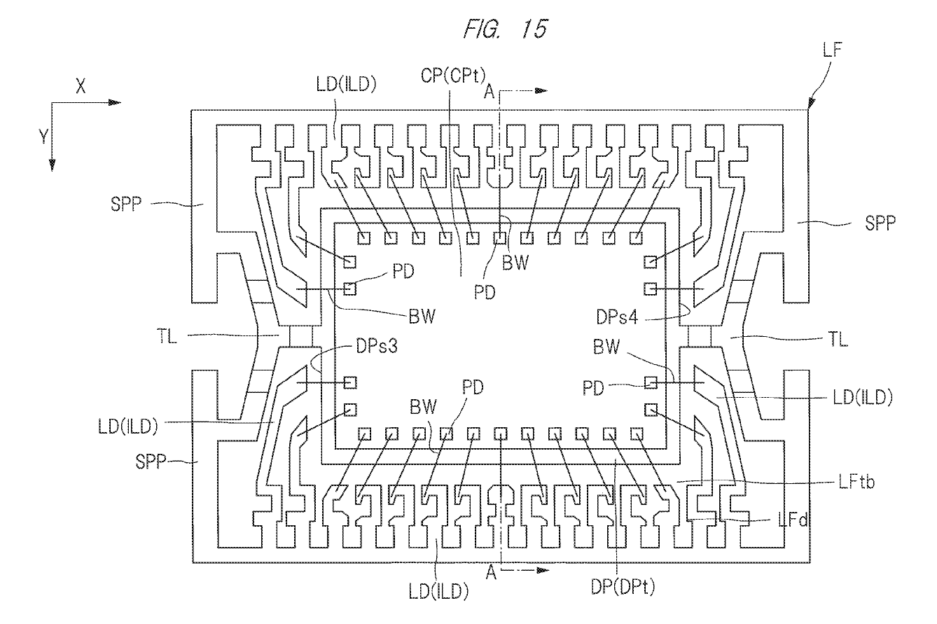

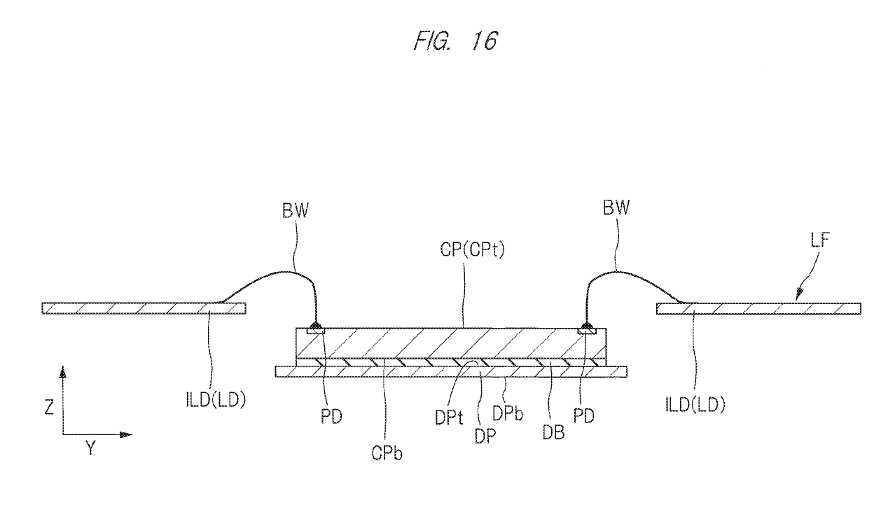

Next, as a wire bonding process shown in FIG. 10, the plurality of pads PD of the semiconductor chip CP and the plurality of leads LD are electrically connected to each other via a plurality of wires (conductive members) BW as shown in FIGS. 15 and 16. FIG. 15 is an enlarged plan view showing a state in which the semiconductor chip and the plurality of leads shown in FIG. 13 are electrically connected to each other via wires, and FIG. 16 is an enlarged cross-sectional view taken along line A-A of FIG. 15.

In this process, one end of the wire BW is bonded to the pad PD and the other end is bonded to the inner lead section ILD of the lead LD. In the example shown in FIG. 16, the pad PD corresponds to the first bond side and the lead LD corresponds to the second bond side. To be specific, first, the tip of the wire BW is melted to form a ball portion. Next, the ball portion is press-bonded to the pad PD corresponding to the first bond side. At this time, the temperature of the press-bonded portion in the press-bonding can be lowered by applying ultrasonic waves to the ball portion of the wire BW.

Next, a wire loop shape is formed by moving a bonding tool (not shown) while sending the wire BW therefrom. Then, a part of the wire BW is connected to the second bonding side (bonding region provided on the inner lead section ILD of the lead LD). In order to improve the bondability with the wire BW, a metal film made of, for example, silver (Ag) or gold (Au) may be formed on a part of the lead LD (bonding region disposed at the tip of the inner lead section ILD).

The method in which a part (end) of the wire is connected to the pad PD of the semiconductor chip CP and then the other part of the wire BW is connected to the bonding region of the lead LD (part of the upper surface of the lead LD) as described above is referred to as a positive bonding method.

Further, in this process, the wires BW are bonded to the plurality of leads LD provided in each of the plurality of device regions LFd (see FIG. 11). As a result, the semiconductor chip CP and the plurality of leads LD are electrically connected via the plurality of wires BW in the respective device regions LFd.

Also, in this process, some of the plurality of wires BW are formed to pass over the short side DPs3 or DPs4 of the die pad DP as shown in FIG. 15.

Further, as shown in FIG. 16, since the difference in height between the lead LD and the die pad DP is large in the present embodiment, the position of the pad PD is lower than the position of the inner lead section ILD of the lead LD with respect to the upper surface DPt of the die pad DP serving as the reference surface. Therefore, the height of the first bonding position is lower than the height of the second bonding position with respect to the upper surface of the die pad DP serving as the reference surface.

4. Sealing Process:

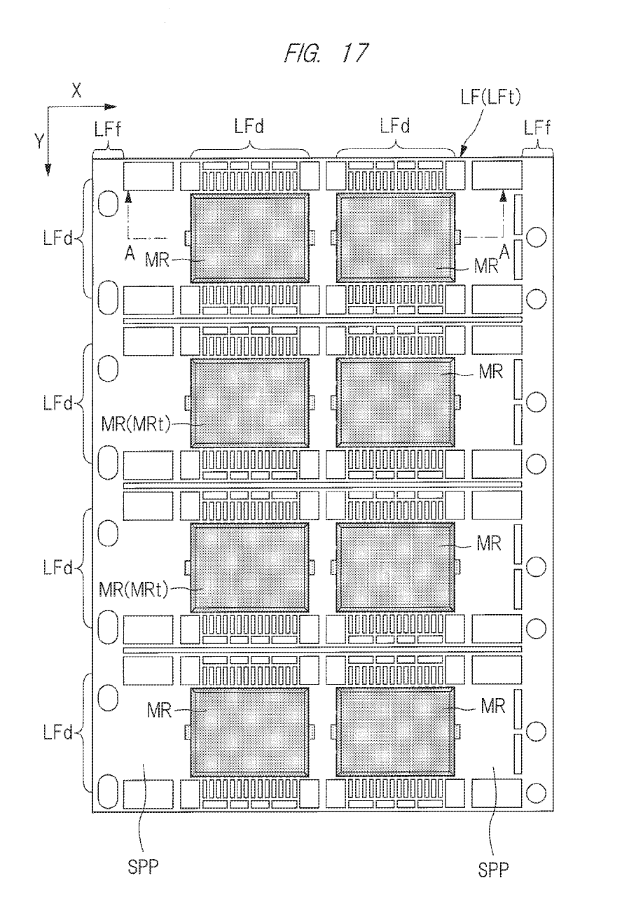

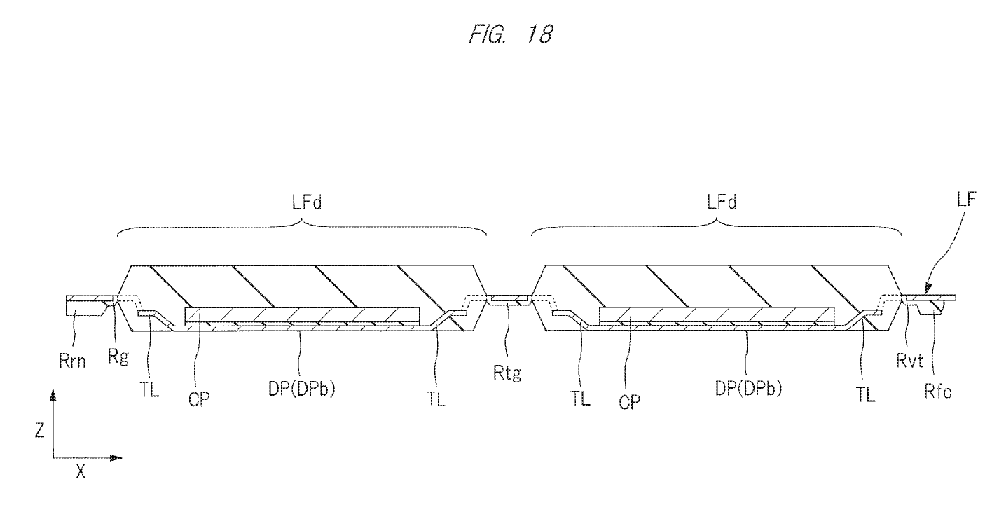

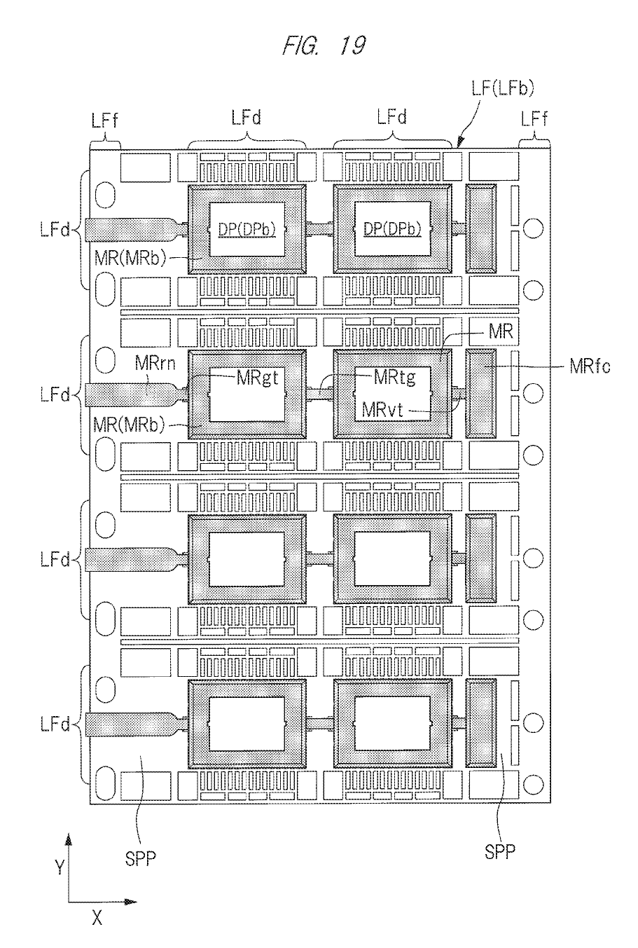

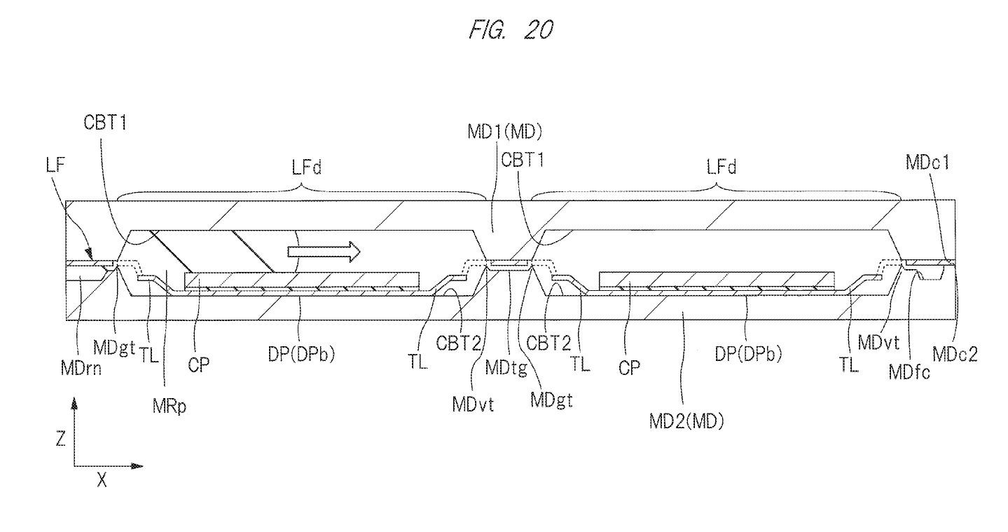

Next, as a sealing process shown in FIG. 10, the sealing body (resin body) MR is formed so as to seal the semiconductor chip CP (see FIG. 15), the plurality of wires BW (see FIG. 15), and a portion (inner lead section) of each of the plurality of leads LD (see FIG. 15) as shown in FIGS. 17 to 19. FIG. 17 is a plan view showing a state in which a sealing body is formed in each device region of the lead frame shown in FIG. 15. Also, FIG. 18 is an enlarged cross-sectional view taken along line A-A of FIG. 17. In addition, FIG. 19 is a plan view showing a surface on the opposite side of the lead frame shown in FIG. 17. Further, FIG. 20 is an enlarged cross-sectional view showing a state in which the lead frame is disposed in a molding die for molding a sealing body in the cross section taken along line A-A of FIG. 17.

In this process, the sealing body MR is individually formed in each of the plurality of device regions LFd as shown in FIG. 17. Also, in the present embodiment, the sealing body MR is formed so that the lower surface DPb of the die pad DP provided in each device region LFd is exposed on the lower surface LFb of the lead frame LF as shown in FIG. 19.

For example, the method of forming the sealing body MR is as follows. That is, in a state where the lead frame LF is sandwiched between pieces of a molding die MD shown in FIG. 20, the softened resin is pressed into the molding die MD and is then hardened to form the sealing body MR. Such a sealing method is referred to as a transfer molding method.

The molding die MD includes an upper die (mold) MD1 disposed on the upper side of the lead frame LF and a lower die (mold) MD2 disposed on the lower side of the lead frame LF. The upper die MD1 has a plurality of cavities (recesses) CBT1 and a clamping surface (die surface, pressing surface, surface) MDc1 surrounding the periphery of the plurality of cavities CBT1 and holding an upper surface LFt (see FIG. 17) of the lead frame LF. In addition, the lower die MD2 has a plurality of cavities (recesses) CBT2 arranged to face the plurality of cavities CBT1 and a clamping surface (die surface, pressing surface, surface) MDc2 arranged to face the clamping surface MDc1 and holding the lower surface LFb (see FIG. 19) of the lead frame LF.

Also, the molding die MD has a gate section MDgt which is a supply port of the resin MRp to the space formed by the cavities CBT1 and CBT2 and a vent section MDvt which is provided opposite to the gate section MDgt via the cavity CBT2. The vent section MDvt is a discharge path for discharging the gas (for example, air) and excessive resin MRp in the space formed by the cavities CBT1 and CBT2 to the outside of the space formed by the cavities CBT1 and CBT2. Leakage of the resin MRp can be suppressed by reducing the opening area of the vent section MDvt.

In addition, in the example of the present embodiment, a through gate MDtg communicating between the adjacent cavities CBT2 is provided between the adjacent cavities CBT2. One end of the through gate MDtg is connected to the vent section MDvt of a first cavity CBT2 and the other end thereof is connected to the gate section MDgt of a second cavity CBT2. In other words, the through gate MDtg is provided so as to connect the adjacent device regions LFd. By connecting the adjacent device regions LFd, the resin MRp can be sequentially supplied to the plurality of device regions LFd. A technique of connecting the plurality of device regions LFd with the through gate MDtg and sequentially supplying the resin MRp in this manner is referred to as a through gate method.

Also, in the example shown in FIG. 20, a runner section MDrn is connected to the gate section MDgt that is not connected to the through gate MDtg. The runner section MDrn is a supply path for supplying the resin MRp from a resin supply source (referred to as cull (not shown)) toward the gate section MDgt. The cross-sectional area of the flow path of the runner section MDrn is larger than the cross-sectional area of the flow path of the gate section MDgt. When supplying the resin MRp to the vicinity of the gate section MDgt through the runner section MDrn having a relatively large cross-sectional area of the flow path, the supply pressure of the resin MRp can be easily adjusted.

Further, in the example shown in FIG. 20, a flow cavity MDfc is connected to the vent section MDvt that is not connected to the through gate MDtg. The flow cavity MDfc is a recess that forms a space to be filled with the resin MRp overflowing from the space formed by the cavities CBT1 and CBT2. By providing the flow cavity MDfc at the end of the supply path of the resin MRp, leakage of the resin MRp in the sealing process can be suppressed. Further, by providing the flow cavity MDfc at the end of the supply path of the resin MRp, the formation of bubbles (voids) in the space formed by the cavities CBT1 and CBT2 can be suppressed. In addition, by providing the flow cavity MDfc at the end of the supply path of the resin MRp, the occurrence of unfilled regions in the space formed by the cavities CBT1 and CBT2 can be suppressed.

In the sealing process of the present embodiment, the sealing resin MRp is injected into the space formed by coupling the cavities CBT1 and CBT2 shown in FIG. 20 through the runner section MDrn and the gate section MDgt. The resin MRp is injected from the gate section MDgt toward the vent section MDvt as schematically shown by an arrow in FIG. 20. By this means, the semiconductor chip CP, the plurality of wires BW (see FIG. 15) and the inner lead sections ILD (see FIG. 15) of the plurality of leads LD (see FIG. 15) are sealed with the resin MRp. Then, the sealing body MR shown in FIGS. 17 to 19 is formed by thermally curing the resin MRp injected to the cavities CBT1 and CBT2.

When the molding die MD shown in FIG. 20 is removed after curing the sealing body MR, a runner resin MRrn, a gate resin MRgt, a main body of the sealing body MR, a through gate resin MRtg, a main body of the sealing body MR, a vent resin MRvt, and a flow cavity resin MRfc are linearly arranged in the X direction on the lower surface LFb of the lead frame LF as shown in FIG. 19. The runner resin MRrn is the resin cured in the runner section MDrn (see FIG. 20) shown in FIG. 20. The gate resin MRgt is the resin cured in the gate section MDgt shown in FIG. 20. The vent resin MRvt is the resin cured in the vent section MDvt shown in FIG. 20. The through gate resin MRtg is the resin cured in the through gate MDtg shown in FIG. 20. Further, the flow cavity resin MRfc is the resin cured in the flow cavity MDfc shown in FIG. 20.

As shown in FIG. 20, the runner section MDrn, the gate section MDgt, the vent section MDvt, the through gate MDtg, and the flow cavity MDfc are provided in the lower die MD2 and are not provided in the upper die MD1 in the present embodiment. As a modification example of the present embodiment, the runner section MDrn, the gate section MDgt, the vent section MDvt, the through gate MDtg, and the flow cavity MDfc may be formed in the upper die MD1. Alternatively, the runner section MDrn, the gate section MDgt, the vent section MDvt, the through gate MDtg, and the flow cavity MDfc may be formed in both the upper die MD1 and the lower die MD2.

However, in the case of the transfer molding method, since the opening area of the gate section MDgt is smaller than the other portions, the gate section MDgt is likely to be worn by the friction with the resin MRp as compared with other portions. From the viewpoint of reducing the change in the supply pressure due to the increase in the opening area of the gate section MDgt, the gate section MDgt is preferably provided in either one of the upper die MD1 and the lower die MD2.

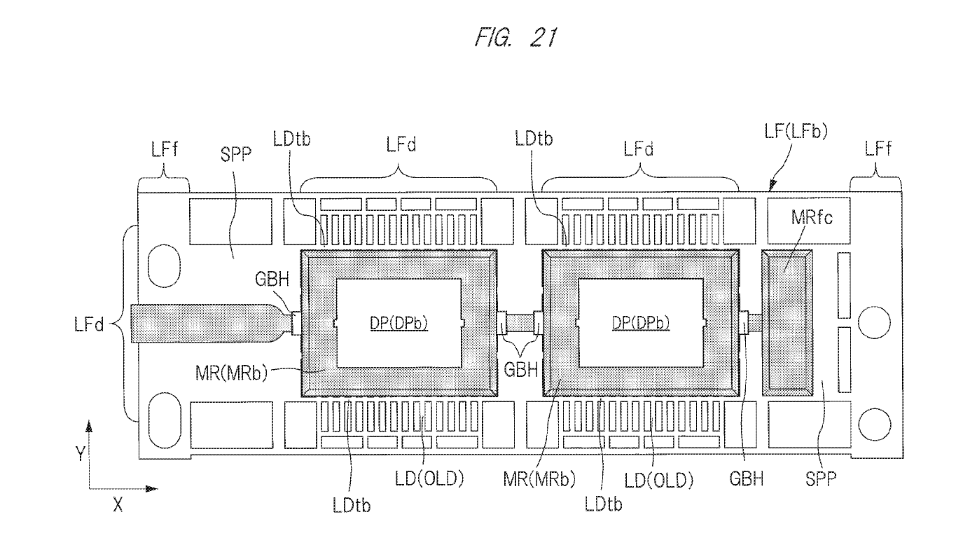

Further, in the sealing process, after the sealing body MR is formed, the connection sections of the gate resin MRgt (see FIG. 19) and the vent resin MRvt (see FIG. 19) connected to the sealing body MR are broken to be separated from the main body of the sealing body MR (gate break process). When the gate break process is completed, through holes GBH penetrating the lead frame LF in the thickness direction are formed on both sides of the main body of the sealing body MR as shown in FIG. 21. FIG. 21 is an enlarged plan view showing a state in which connection sections of the gate resin and the vent resin shown in FIG. 19 are broken and the through holes penetrating the lead frame in the thickness direction are formed.

In the gate break process, the connection section connected with the sealing body MR is broken by bending it from the side where the gate resin MRgt and the vent resin MRvt are present while holding the surface opposite to the surface on which the gate resin MRgt and the vent resin MRvt are formed. Namely, when the gate resin MRgt and the vent resin MRvt are formed on the mounting surface, the side (upper surface LFt shown in FIG. 17) opposite to the mounting surface is held by a jig (not shown) in the gate break process. In this case, since it is possible to suppress the mounting surface from being damaged by the holding jig, the gate section MDgt is preferably provided in the lower die MD2.

<Deformation of Suspension Lead in Sealing Process>

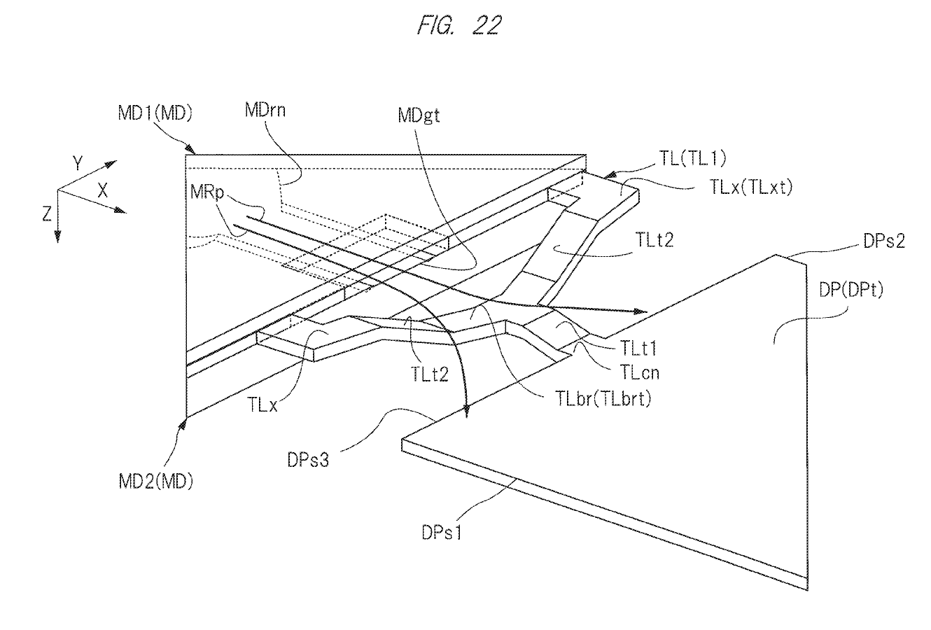

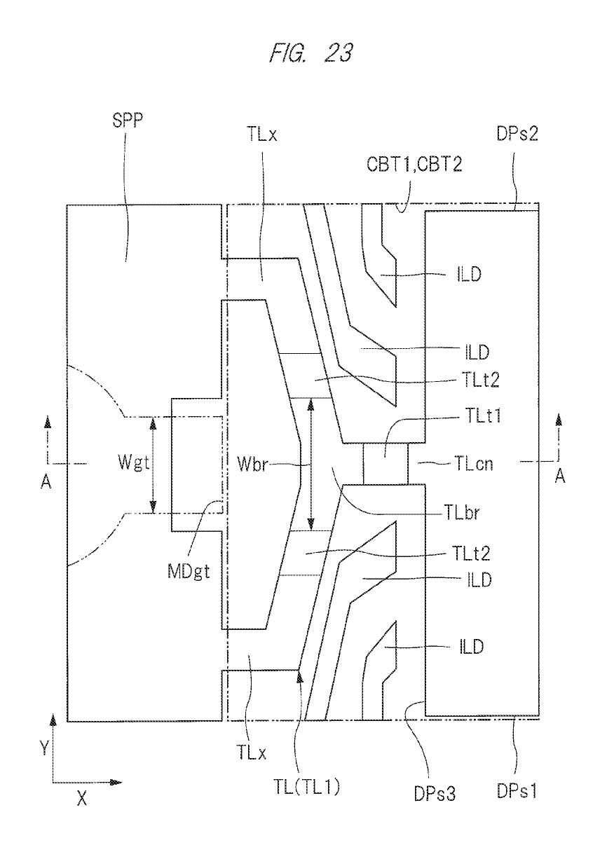

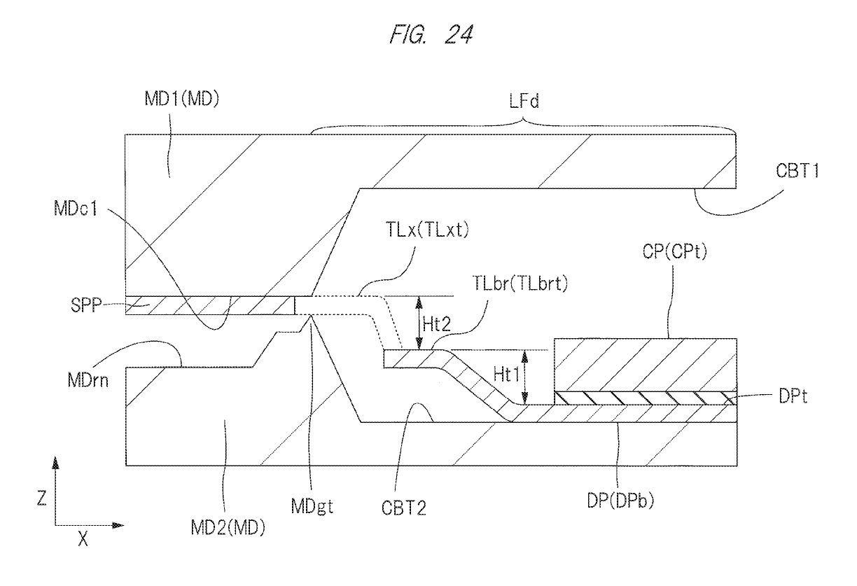

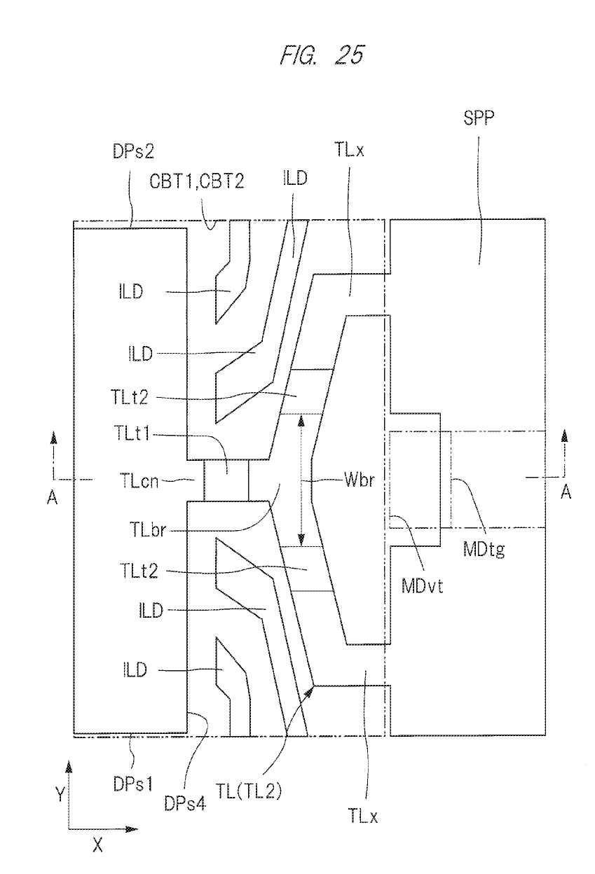

Here, the relationship between the resin supply path and the ease of deformation of the suspension lead in the sealing process will be described. FIG. 22 is an explanatory view schematically showing the resin supply direction from the gate section in the sealing process. Also, FIG. 23 is an enlarged plan view of the periphery of the gate section shown in FIG. 19. In addition, FIG. 24 is an enlarged cross-sectional view taken along line A-A of FIG. 23. Further, FIG. 25 is an enlarged plan view of the periphery of the through gate shown in FIG. 19.

As described with reference to FIG. 6, when the height difference between the protruding section OLD1 and the mounted section OLD2 is increased, the length of the inclined section OLDS of the outer lead section OLD of the lead LD becomes longer, and the stress reduction function of the lead LD is improved. This improves the mounting reliability of the semiconductor device PKG1 after mounting. However, the exposed-surface connection section TLx of the suspension lead TL shown in FIG. 7 and the protruding section OLD1 of the lead LD shown in FIG. 6 are located at the same height. Hence, in order to expose a part of the die pad DP, the height difference between the exposed surface TLxs of the suspension lead TL and the die pad DP becomes large. Further, when only one offset section TLth1 is provided between the exposed surface TLxs and the die pad DP like in the suspension lead TLh1 shown in FIG. 30, the offset section TLth1 becomes long to be easily deformed.

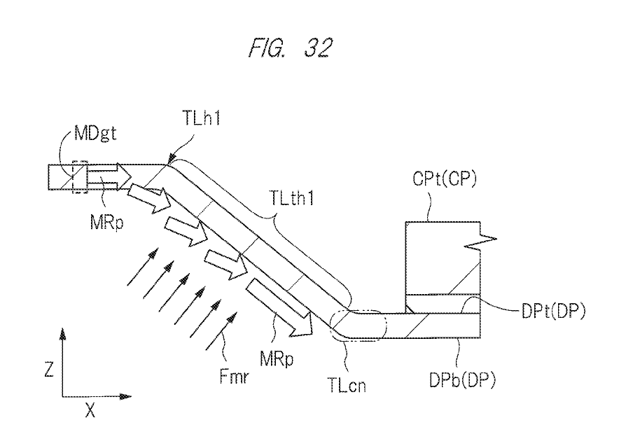

Here, the study by the inventor of the present application has revealed that, in the case where the suspension lead TL is present on the straight line connecting the gate section MDgt and the vent section MDvt shown in FIG. 20 and in the vicinity of the gate section MDgt, the lower surface DPb of the die pad DP is covered with the sealing body MR because the suspension lead TL is deformed by the supply pressure of the resin MRp from the gate section MDgt. To be specific, as schematically shown by arrows in FIG. 32, when the offset section TLth1 of the suspension lead TL is disposed in the vicinity of the gate section MDgt, pressing force Fmr is applied in the thickness direction (height direction, the Z direction shown in FIG. 32) to the offset section TLth1 in contact with the resin MRp. Since the supply pressure of the resin MRp is high in the vicinity of the gate section MDgt, the strong pressing force Fmr acts on the offset section TLth1 of the suspension lead TL. FIG. 32 is an explanatory view schematically showing a state in which a pressing force is applied to the suspension lead having the structure shown in FIG. 31 in the sealing process.

As shown in FIG. 32, this pressing force Fmr acts to push the suspension lead TL and the die pad DP connected to the suspension lead TL upward (in a direction from the lower surface DPb toward the upper surface DPt of the die pad DP). Further, a part of the resin MRp in contact with the suspension lead TL flows downward along the suspension lead TL. Accordingly, when the die pad DP is in a state of being lifted upward, apart of the resin MRp flows in toward the lower surface DPb of the die pad DP, and a part of the die pad DP is sealed with the resin MRp. In this case, the exposed area of the die pad DP is reduced, which causes the deterioration of heat dissipation characteristics.

Although the suspension lead TLh1 described with reference to FIG. 30 is taken in the description of FIG. 32, since the offset section TLth2 is disposed in the vicinity of the gate section MDgt (see FIG. 32) also in the suspension lead TLh2 described with reference to FIG. 31, a part of the die pad DP may be sealed with the resin MRp (see FIG. 32) in some cases.

Thus, in the sealing process of the present embodiment, the gate section MDgt is provided at a position higher than the branch section TLbr with respect to the upper surface DPt that is a chip mounting surface as shown in FIG. 22. Therefore, the resin MRp supplied from the gate section is likely to be supplied to the upper side of the branch section TLbr. Further, the gate section MDgt of the molding die MD is provided between the plurality of exposed-surface connection sections TLx in plan view (in detail, in the Y direction). To be specific, the gate section MDgt is provided between the two exposed-surface connection sections TLx in the Y direction orthogonal to the X direction. In this case, as schematically shown by arrows in FIG. 22, most of the resin MRp supplied from the gate section MDgt passes over the branch section TLbr of the suspension lead TL and moves toward the die pad DP. Hence, in the case of the suspension lead TL of the present embodiment, the pressing force Fmr shown in FIG. 32 is less likely to be applied. Further, when apart of the resin MRp goes under the branch section TLbr, the pressing force Fmr (see FIG. 32) is generated to the offset section TLt1. However, since the other part of the resin MRp flows over an upper surface TLbrt of the branch section TLbr and an upper surface of the offset section TLt2, a pressing force is generated in a direction to cancel the pressing force Fmr. As a result, it is possible to suppress the suspension lead TL and the die pad DP connected to the suspension lead TL from being deformed so as to be lifted upward.

Also, as shown in FIG. 23, a width Wgt of the gate section MDgt is narrower than a width Wbr of the branch section TLbr of the suspension lead TL in plan view (in detail, in the Y direction). In other words, the width Wgt of the gate section MDgt is narrower than a separation distance (width Wbr) between the two offset sections TLt2 facing each other in plan view. Hence, when the gate section MDgt is extended in the X direction shown in FIG. 23, an extended line of the gate section MDgt in the X direction is arranged between the plurality of offset sections TLt2. In this case, as schematically shown by arrows in FIG. 22, most of the resin MRp supplied from the gate section MDgt is not in contact with the offset section TLt2 of the suspension lead TL, and passes over the branch section TLbr and moves toward the die pad DP. Accordingly, the deformation of the suspension lead TL caused by pressing the offset section TLt2 in the X direction can be suppressed. Note that the width Wgt of the gate section MDgt is the length of the gate section MDgt in the Y direction orthogonal to the X direction. Also, the width Wbr of the branch section TLbr is the length of the branch section TLbr in the Y direction orthogonal to the X direction.

Further, from the viewpoint of enabling most of the resin MRp to easily pass over the branch section TLbr of the suspension lead TL, the height of the branch section TLbr is preferably low. As shown in FIG. 22, since the offset section TLt2 exists between the branch section TLbr and each of the plurality of exposed-surface connection sections TLx, the height of the upper surface TLbrt of the branch section TLbr is at least lower than the height of an upper surface TLxt of the exposed-surface connection section TLx. In the example shown in FIG. 24, the ratio of a height difference Ht1 between the upper surface TLbrt of the branch section TLbr and the upper surface DPt of the die pad DP to a height difference Ht2 between the upper surface TLxt of the exposed-surface connection section TLx and the upper surface TLbrt of the branch section TLbr is 1:1. However, the ratio of the height difference Ht1 to the height difference Ht2 is not limited to 1:1, and various modification examples can be applied.

Further, as shown in FIG. 24, when the height of the lower end of the opening formed by the gate section MDgt is higher than the height of the upper surface TLbrt of the branch section TLbr with respect to (on the basis of) the upper surface DPt of the die pad DP, the resin MRp is likely to be supplied to the upper side of the branch section TLbr. Also, in the example shown in FIG. 24, the upper surface TLbrt of the branch section TLbr is provided at a position lower than the front surface CPt of the semiconductor chip CP with respect to the upper surface DPt of the die pad DP.

Note that, in the case of suppressing a part of the lower surface DPb of the die pad DP from being sealed due to deformation of the suspension lead TL1 in the sealing process, the structure of the suspension lead TL1 disposed in the vicinity of the gate section MDgt shown in FIG. 22 is important. Accordingly, the suspension lead TL2 on the side of the vent section MDvt shown in FIG. 25 may have the structure similar to the suspension lead TLh1 shown in FIG. 30 or the structure similar to the suspension lead TLh2 shown in FIG. 31.

However, from the viewpoint of improving the support strength for the die pad DP, as shown in FIG. 25, the suspension lead TL2 has preferably the structure similar to that of the suspension lead TL1 shown in FIG. 23. Namely, the suspension lead TL2 of the present embodiment has the offset section TLt1 and the offset sections TLt2 between the portions exposed from the sealing body MR (see FIG. 19) and the die pad DP. Hence, the suspension lead TL2 is hard to deform as compared with the suspension lead TLh1 shown in FIG. 30, and it is thus possible to improve the support strength for the die pad DP.

In addition, each of the plurality of offset sections TLt2 included in the suspension lead TL2 extends in a direction intersecting the X direction. Thus, in the suspension lead TL according to the present embodiment, the planar distance L1 (see FIG. 2) from the portion exposed from the sealing body MR (see FIG. 19) to the die pad DP can be shortened as compared with the examination example shown in FIG. 31. As a result, the mounting area of the semiconductor device PKG1 (see FIG. 2) can be reduced.

Further, as shown in FIG. 25, the vent section MDvt of the molding die MD (see FIG. 20) is provided between the plurality of exposed-surface connection sections TLx in plan view (in detail, in the Y direction). As shown in FIG. 20, the through gate method in which the device regions LFd adjacent to each other are connected by the through gate MDtg and the resin MRp is sequentially supplied is adopted in the sealing process in the present embodiment. In the case of adopting the through gate method, the vent section MDvt of the first device region LFd and the gate section MDgt of the second device region LFd are linearly arranged in the X direction via the through gate MDtg. Hence, if the vent section MDvt is provided between the exposed-surface connection sections TLx, the gate section MDgt can be easily arranged between the plurality of exposed-surface connection sections TLx in the second device region LFd as shown in FIG. 23.

Further, the tab connection section TLcn of the suspension lead TL1 is connected to the center of the short side DPs3 of the die pad DP as shown in FIG. 23, and the tab connection section TLcn of the suspension lead TL2 is connected to the center of the short side DPs4 of the die pad DP as shown in FIG. 25. When the suspension leads TL1 and TL2 are connected to each center of the sides of the die pad DP in this manner, the pressing force from the resin MRp (see FIG. 20) is applied in proper balance with respect to the fulcrum of the die pad DP (the connection section of the suspension lead TL) in the sealing process. Accordingly, it is possible to suppress the die pad DP from rotating due to the supply pressure of the resin MRp.

Also, in the present embodiment, some of the plurality of inner lead sections ILD are arranged along the short side DPs3 of the die pad DP as shown in FIG. 23. In addition, others of the plurality of inner lead sections ILD are arranged along the short side DPs4 of the die pad DP as shown in FIG. 25. By effectively utilizing the space in which the suspension lead TL1 (see FIG. 23) or TL2 (see FIG. 25) is not arranged as the arrangement space of the inner lead sections ILD in this manner, the arrangement density of the terminals of the semiconductor device can be increased.

5. Plating Process:

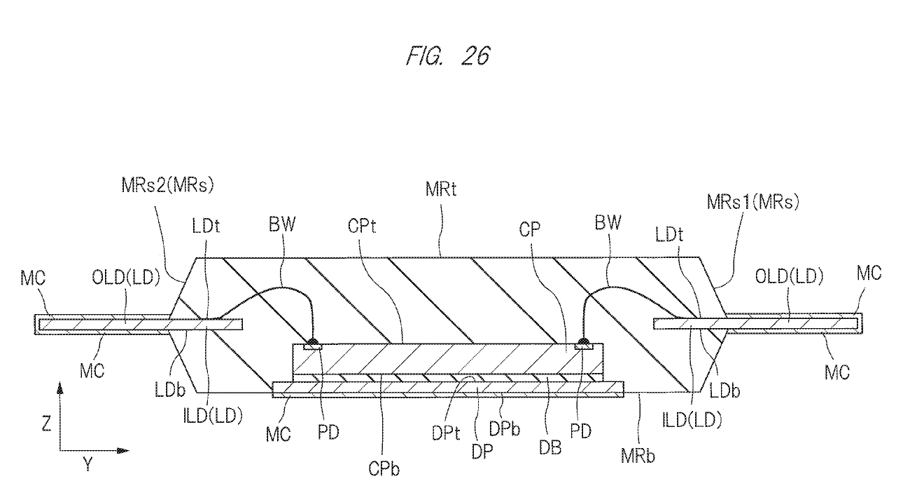

Next, as a plating process shown in FIG. 10, the metal film MC is formed on the exposed surfaces of the plurality of leads LD and the die pad DP as shown in FIG. 26. FIG. 26 is an enlarged cross-sectional view showing a state in which metal films are formed on exposed surfaces of the leads and the die pad shown in FIG. 21.

The metal film MC of the present embodiment is made of so-called lead-free solder which contains substantially no lead (Pb), for example, pure tin (Sn), tin-bismuth (Sn—Bi), tin-copper-silver (Sn—Cu—Ag) or the like.

As the method of forming the metal film MC, a so-called electrolytic plating method in which the lead frame LF is immersed in a plating solution contained in a plating bath (not shown) and the metal film MC is deposited on the exposed surface of the lead frame LF by applying a DC voltage or the like can be adopted.

Note that a method in which wettability of solder at the time of mounting onto a mounting board (not shown) is improved by forming the metal film MC made of solder or the like after the sealing process (post-plating method) has been described in the present embodiment, but the following modification example can be applied. That is, as a technique for improving wettability of solder on the terminal surface of the semiconductor device, a so-called pre-plating method in which a metal film is formed on the surface of the lead frame in advance can also be applied in addition to the post-plating method.

When the pre-plating method is applied, a surface metal film for improving wettability of solder is formed in advance on the entire exposed surface of the lead frame in the lead frame preparation process shown in FIG. 10. In the process of forming the surface metal film, for example, a surface metal film made of nickel (Ni), palladium (Pd), or gold (Au) is formed by a plating method. Also, when the pre-plating method is applied, the plating process shown in FIG. 10 can be omitted.

6. Lead Shaping Process:

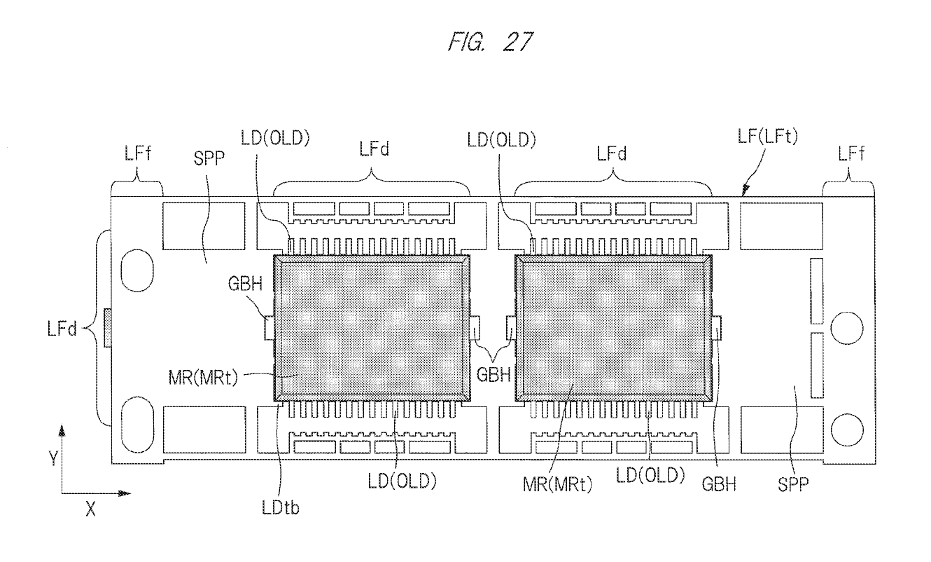

Next, as a lead shaping process shown in FIG. 10, the outer lead sections OLD of the plurality of leads LD coupled by the tie bar LDtb (see FIG. 21) are divided as shown in FIG. 27, and the lead LD is shaped by bending the outer lead section OLD as shown in FIG. 4. FIG. 27 is an enlarged plan view showing a state in which the plurality of leads shown in FIG. 26 are divided and shaped. Note that FIG. 27 shows the plane of the upper surface LFt of the lead frame LF shown in FIG. 21.

By this process, the plurality of leads LD are separated respectively, and parts other than the suspension leads TL (see FIGS. 23 and 25) are separated from the support member SPP.

As a method of dividing the plurality of leads LD, for example, the plurality of leads LD can be divided by press working using a punch (cutting blade) and a die (supporting member). Further, as a method of shaping the outer lead section OLD of the lead LD, for example, the outer lead section OLD can be shaped by using a bending punch (pressing tool for bending) and a die (supporting member). From the viewpoint of improving the bending accuracy of the lead LD, the tip of the outer lead section OLD is preferably cut off in advance before bending the lead LD.

7. Singulation Process:

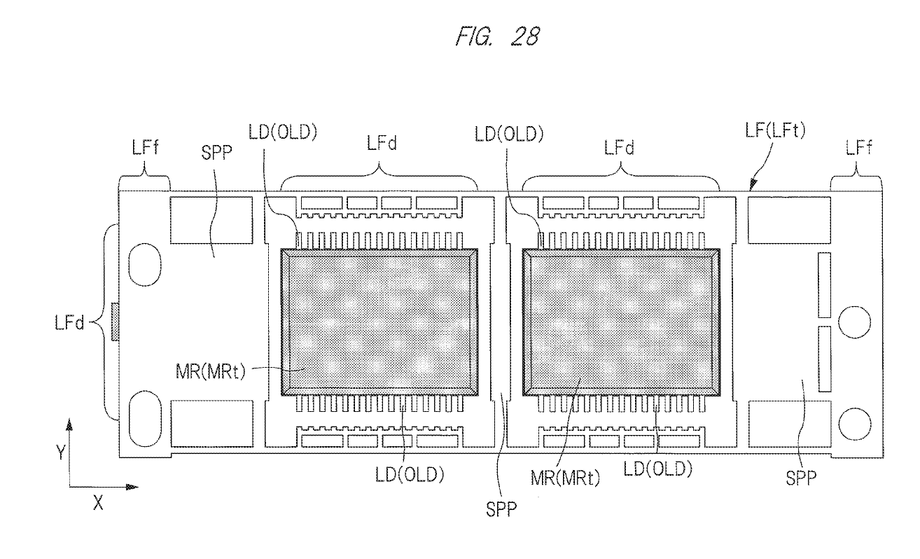

Next, as a singulation process shown in FIG. 10, each of the plurality of device regions LFd is separated by cutting the boundary between the device region LFd and the support member SPP as shown in FIG. 28. FIG. 28 is an enlarged plan view showing a state in which a plurality of device regions of the lead frame shown in FIG. 27 are separated from each other.

In this process, by cutting the boundary between the device region LFd and the support member SPP, each of the plurality of device regions LFd is separated from the support member SPP. As a method of cutting the lead frame LF, for example, the lead frame LF can be cut by press working using a punch (cutting blade) and a die (supporting member).

After this process, necessary inspections and tests such as appearance inspection, electrical test, etc. are performed, and one that has passed the inspections and tests becomes the semiconductor device PKG1 of the finished product shown in FIG. 1. Then, the semiconductor device PKG1 is shipped, or the semiconductor device PKG1 is mounted on the mounting board MB as described with reference to FIG. 6.

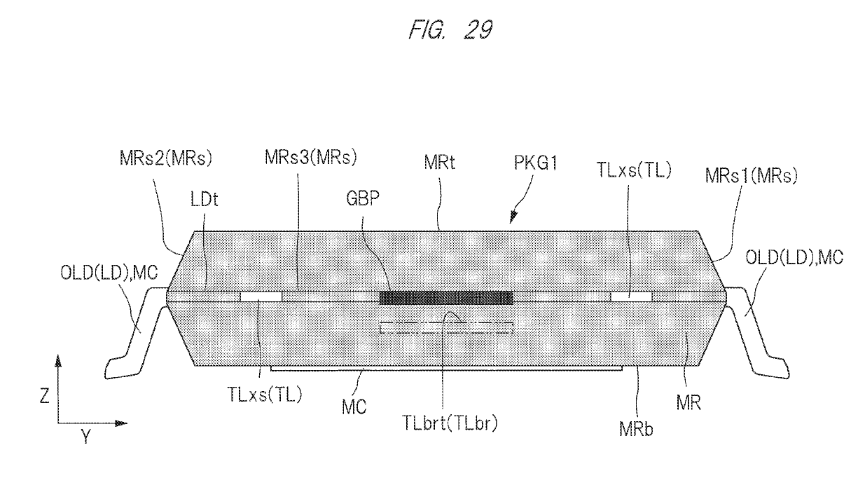

In the semiconductor device manufactured by the manufacturing method described above, a part (exposed surface TLxs) of the suspension lead TL is exposed from the sealing body MR at a plurality of places (two places in FIG. 29) in a side view seen from the short side MRs3 of the sealing body MR as shown in FIG. 29. FIG. 29 is a side view of the semiconductor device shown in FIG. 1 seen from the short side. The two exposed surfaces TLxs are provided between the upper surface MRt and the lower surface MRb, namely, at the middle between the upper surface MRt and the lower surface MRb in FIG. 29. Also, a gate break section GBP, which is a trace of the gate break process described above, remains between the two exposed surfaces TLxs. Since the gate break section GBP is a surface formed by breaking the resin in the gate break process, the surface roughness of the gate break section GBP is higher than that of the side surface MRs3. The gate break section GBP is provided at a position higher than the branch section TLbr of the suspension lead TL in side view. To be specific, the lower end of the gate break section GBP is provided at a position higher than the upper surface TLbrt of the branch section TLbr (position closer to the upper surface MRt).

Further, in the present embodiment, the suspension lead TL1 and the suspension lead TL2 form a line symmetrical structure as shown in FIG. 3. For this reason, although not shown in the drawing, the same structure is seen also in the side view of the short side MRs4 shown in FIG. 2.

### Modification Example

In the foregoing, the invention made by the inventor of the present invention has been concretely described based on the embodiments. However, it is needless to say that the present invention is not limited to the foregoing embodiments and various modifications and alterations can be made within the scope of the present invention.

For example, in the embodiment described above, various techniques applied to the semiconductor device PKG1 and their effects have been sequentially described by referring to the semiconductor device PKG1 and the manufacturing method thereof. However, a semiconductor device to which some of the plurality of techniques described above are applied may be used as a modification example.

For example, if attention is paid to the effect of reducing the mounting area of the semiconductor device PKG1 (see FIG. 2) by shortening the planar distance L1 from the exposed surface TLxs of the suspension lead TL (see FIG. 3) to the die pad DP shown in FIG. 2, the positional relationship between the suspension lead TL and the gate section MDgt of the molding die MD shown in FIG. 22 is not particularly limited. Further, if at least one of the suspension leads TL1 and TL2 shown in FIG. 3 has the structure shown in FIG. 7, the effect of reducing the mounting area of the semiconductor device can be obtained as compared with the examination examples shown in FIGS. 30 and 31.

Further, in order to suppress the deformation of the suspension lead TLh1 caused by being pressed by the resin MRp as shown in FIG. 32, it is particularly preferable that the gate section MDgt of the molding die MD is provided between the plurality of exposed-surface connection sections TLX in the Y direction as shown in FIG. 22. However, if the extending directions of the plurality of offset sections TLt2 intersect the supply direction (X direction) of the resin MRp, the pressing force Fmr shown in FIG. 32 is less likely to be applied. Thus, as long as each of the plurality of offset sections TLt2 connected to the branch section TLbr extends at least in a direction different from the X direction, the deformation of the suspension lead TL can be suppressed as compared with the examination example shown in FIG. 32.

Further, from the viewpoint of suppressing the rotation of the die pad DP due to the supply pressure of the resin MRp in the sealing process, the tab connection section TLcn of the suspension lead TL is preferably connected to the center of the short side DPs3 of the die pad DP as shown in FIG. 22. However, when it is not necessary to take the deformation of the die pad DP into consideration depending on the degree of the supply pressure of the resin MRp or the like, the tab connection section TLcn can be connected to any position of the short side DPs3 of the die pad DP.

Further, for example, the various modification examples described above can be combined with each other.

In addition, some of the contents described in the embodiment above will be described below.

[Appendix 1]

A semiconductor device including:

a chip mounting section having a chip mounting surface and a back surface opposite to the chip mounting surface;

a plurality of suspension leads connected to the chip mounting section;

a semiconductor chip mounted on the chip mounting surface of the chip mounting section;

a plurality of leads provided around the semiconductor chip and electrically connected to the semiconductor chip; and

a sealing body that seals the semiconductor chip so that the back surface of the chip mounting section is exposed,

wherein the sealing body has a first long side extending in a first direction, a second long side opposite to the first long side, a first short side extending in a second direction intersecting the first direction, and a second short side opposite to the first short side in plan view,

the plurality of suspension leads include a first suspension lead extending from the chip mounting section toward the first short side of the sealing body and a second suspension lead extending from the chip mounting section toward the second short side of the sealing body,

the first suspension lead includes:

a first tab connection section connected to the chip mounting section and extending in the first direction;

a first branch section provided at a position higher than the first tab connection section with respect to the chip mounting surface and branching in a plurality of directions intersecting the first direction;

a plurality of first exposed-surface connection sections provided at positions higher than the first branch section and having one ends connected to a plurality of first exposed surfaces exposed from the sealing body on the first short side;

a first offset section connected to the first tab connection section and the first branch section; and

a plurality of second offset sections each having one end connected to the first branch section and the other end connected to each of the plurality of first exposed-surface connection sections,

the first short side of the sealing body has a first portion having surface roughness higher than that of a side surface of the sealing body, and

the first portion is provided at a position higher than the first branch section with respect to the chip mounting surface in a side view of the sealing body seen from the first short side.

[Appendix 2]

The semiconductor device described in appendix 1,

wherein the first portion is provided between the plurality of first exposed surfaces in the side view of the sealing body seen from the first short side.

[Appendix 3]

The semiconductor device described in appendix 2,

wherein a width of the first portion in the second direction is narrower than a width of the first branch section in the second direction.

[Appendix 4]

The semiconductor device described in appendix 1,

wherein a height of a lower end of the first portion is higher than a height of an upper surface of the branch section with respect to the chip mounting surface of the chip mounting section.

[Appendix 5]

The semiconductor device described in appendix 1,

wherein the second suspension lead includes:

a second tab connection section connected to the chip mounting section and extending in the first direction;

a second branch section provided at a position higher than the second tab connection section with respect to the chip mounting surface and branching in a plurality of directions intersecting the first direction;

a plurality of second exposed-surface connection sections provided at positions higher than the second branch section and each having one end exposed from the sealing body on the second short side;

a third offset section connected to the second tab connection section and the second branch section; and

a plurality of fourth offset sections each having one end connected to the second branch section and the other end connected to each of the plurality of second exposed-surface connection sections.

[Appendix 6]

The semiconductor device described in appendix 1,

wherein the chip mounting section has a third long side extending in the first direction, a fourth long side opposite to the third long side, a third short side extending in the second direction, and a fourth short side opposite to the third short side in plan view, and

the first tab connection section of the first suspension lead is connected to a center of the third short side of the chip mounting section, and the second tab connection section of the second suspension lead is connected to a center of the fourth short side of the chip mounting section.

### REFERENCE SIGNS LIST

BW wire (conductive member)
CBT1, CBT2 cavity (recess)
CP semiconductor chip
CPb back surface (main surface, lower surface)
CPs side surface
CPt front surface (main surface, upper surface)
DB die bonding material (adhesive)
DP die pad (chip mounting section, tab)
DPb lower surface
DPs1, DPs2 long side (side)
DPs3, DPs4 short side (side)
DPt upper surface (chip mounting surface)
Fmr pressing force
GBH through hole
GBP gate break section
Ht1, Ht2 height difference
ILD inner lead section
L1 planar distance
LD lead (terminal, external terminal)
LDb lower surface (mounting surface, lead lower surface)
LDt upper surface (wire bonding surface, lead upper surface)
LDtb tie bar
LF lead frame
LFb lower surface
LFd device region (product formation region)
LFf outer frame
LFt upper surface
LFtb tie bar (lead coupling section)
LNDa land
MB mounting board (motherboard, wiring board)
MBt upper surface (mounting surface)
MC metal film (metal coating film)
MD molding die
MD1 upper die (mold)
MD2 lower die (mold)
MDc1, MDc2 clamping surface (die surface, pressing surface, surface)
MDfc flow cavity
MDgt gate section
MDrn runner section
MDvt vent section
MR sealing body (resin body)
MRb lower surface (back surface, mounting surface, sealing body lower surface)
MRfc flow cavity resin
MRgt gate resin
MRp resin
MRrn runner resin
MRs side surface (sealing body side surface)
MRs1, MRs2 long side (side)
MRs3, MRs4 short side (side)
MRt upper surface (sealing body upper surface)
MRtg through gate resin
MRvt vent resin
OLD outer lead section
OLD1 protruding section
OLD2 mounted section
OLDS inclined section
PD pad (electrode, bonding pad)
PKG1 semiconductor device
SD bonding material
SPP support member
TL, TL1, TL2, TLh1, TLh2 suspension lead
TLbr branch section
TLbrt upper surface
TLcn tab connection section (part)
TLt1, TLt2, TLth1, TLth2 offset section (inclined section)
TLx exposed-surface connection section
TLxs exposed surface
TLxt upper surface
TM1 terminal (lead connection terminal, land)
TM2 terminal (die pad connection terminal, land)
Wbr, Wgt width

1. A manufacturing method of a semiconductor device, comprising the steps of:
(a) preparing a lead frame including a chip mounting section having a chip mounting surface and a back surface opposite to the chip mounting surface, a plurality of suspension leads connected to the chip mounting section, a semiconductor chip mounted on the chip mounting surface of the chip mounting section, and a plurality of leads provided around the semiconductor chip and electrically connected to the semiconductor chip; and
(b) placing the chip mounting section and the semiconductor chip in a cavity of a molding die, and then forming a sealing body by supplying resin into the cavity so that the semiconductor chip is sealed and the back surface of the chip mounting section is exposed,
wherein the sealing body has a first long side extending in a first direction, a second long side opposite to the first long side, a first short side extending in a second direction intersecting the first direction, and a second short side opposite to the first short side in plan view,
the plurality of suspension leads include a first suspension lead extending from the chip mounting section toward the first short side of the sealing body and a second suspension lead extending from the chip mounting section toward the second short side of the sealing body, and
the first suspension lead includes:
a first tab connection section connected to the chip mounting section and extending in the first direction;
a first branch section provided at a position higher than the first tab connection section with respect to the chip mounting surface and branching in a plurality of directions intersecting the first direction;
a plurality of first exposed-surface connection sections provided at positions higher than the first branch section and each having one end connected to a portion exposed from the sealing body on the first short side;
a first offset section connected to the first tab connection section and the first branch section; and
a plurality of second offset sections each having one end connected to the first branch section and the other end connected to each of the plurality of first exposed-surface connection sections.

2. The manufacturing method of a semiconductor device according to claim 1,
wherein, in the step (b), the resin is supplied from a gate section of the molding die provided on the first short side of the sealing body, and
the gate section is provided at a position higher than the first branch section with respect to the chip mounting surface.

3. The manufacturing method of a semiconductor device according to claim 2,
wherein the gate section of the molding die is provided between the plurality of first exposed-surface connection sections in plan view.

4. The manufacturing method of a semiconductor device according to claim 3,
wherein a width of the gate section in the second direction is narrower than a width of the first branch section in the second direction.

5. The manufacturing method of a semiconductor device according to claim 2,
wherein a height of a lower end of an opening formed by the gate section is higher than a height of an upper surface of the first branch section with respect to the chip mounting surface of the chip mounting section.

6. The manufacturing method of a semiconductor device according to claim 2,
wherein the second suspension lead includes:
a second tab connection section connected to the chip mounting section and extending in the first direction;
a second branch section provided at a position higher than the second tab connection section with respect to the chip mounting surface and branching in a plurality of directions intersecting the first direction;
a plurality of second exposed-surface connection sections provided at positions higher than the second branch section and each having one end exposed from the sealing body on the second short side;
a third offset section connected to the second tab connection section and the second branch section; and
a plurality of fourth offset sections each having one end connected to the second branch section and the other end connected to each of the plurality of second exposed-surface connection sections.

7. The manufacturing method of a semiconductor device according to claim 6,
wherein, in the step (b), the resin is supplied from the gate section of the molding die provided on the first short side of the sealing body, and the resin is discharged from a vent section of the molding die provided on the second short side of the sealing body, and
the gate section is provided between the plurality of first exposed-surface connection sections, and the vent section is provided between the plurality of second exposed-surface connection sections in plan view.

8. The manufacturing method of a semiconductor device according to claim 6,
wherein the chip mounting section has a third long side extending in the first direction, a fourth long side opposite to the third long side, a third short side extending in the second direction, and a fourth short side opposite to the third short side in plan view, and
the first tab connection section of the first suspension lead is connected to a center of the third short side of the chip mounting section, and the second tab connection section of the second suspension lead is connected to a center of the fourth short side of the chip mounting section.

9. The manufacturing method of a semiconductor device according to claim 1,
wherein the chip mounting section has a third long side extending in the first direction, a fourth long side opposite to the third long side, a third short side extending in the second direction, and a fourth short side opposite to the third short side in plan view,
the plurality of leads respectively include inner lead sections sealed in the sealing body in the step (b) and outer lead sections protruding from the sealing body,
the plurality of outer lead sections are arranged along the first long side and the second long side of the sealing body and are not arranged on the first short side and the second short side of the sealing body, and
the plurality of inner lead sections are arranged along the third long side, the fourth long side, and the third short side of the chip mounting section.

10. The manufacturing method of a semiconductor device according to claim 1,
wherein inclination angles of the first offset section and the plurality of second offset sections with respect to the chip mounting surface are less than 45 degrees.

11. The manufacturing method of a semiconductor device according to claim 1,
wherein the plurality of leads and a plurality of pads included in the semiconductor chip are electrically connected via a plurality of wires.

12. The manufacturing method of a semiconductor device according to claim 1,
wherein each of a plurality of pads included in the semiconductor chip is provided at a position lower than the plurality of leads with respect to the chip mounting surface.

13. A semiconductor device comprising:
a chip mounting section having a chip mounting surface and a back surface opposite to the chip mounting surface;
a plurality of suspension leads connected to the chip mounting section;
a semiconductor chip mounted on the chip mounting surface of the chip mounting section;
a plurality of leads provided around the semiconductor chip and electrically connected to the semiconductor chip; and
a sealing body that seals the semiconductor chip so that the back surface of the chip mounting section is exposed,
wherein the sealing body has a first long side extending in a first direction, a second long side opposite to the first long side, a first short side extending in a second direction intersecting the first direction, and a second short side opposite to the first short side in plan view,
the plurality of suspension leads include a first suspension lead extending from the chip mounting section toward the first short side of the sealing body and a second suspension lead extending from the chip mounting section toward the second short side of the sealing body, and
the first suspension lead includes:
a first tab connection section connected to the chip mounting section and extending in the first direction;
a first branch section provided at a position higher than the first tab connection section with respect to the chip mounting surface and branching in a plurality of directions intersecting the first direction;
a plurality of first exposed-surface connection sections provided at positions higher than the first branch section and each having one end connected to a portion exposed from the sealing body on the first short side;
a first offset section connected to the first tab connection section and the first branch section; and
a plurality of second offset sections each having one end connected to the first branch section and the other end connected to each of the plurality of first exposed-surface connection sections.

14. The semiconductor device according to claim 13,
wherein the second suspension lead includes:
a second tab connection section connected to the chip mounting section and extending in the first direction;
a second branch section provided at a position higher than the second tab connection section with respect to the chip mounting surface and branching in a plurality of directions intersecting the first direction;
a plurality of second exposed-surface connection sections provided at positions higher than the second branch section and each having one end exposed from the sealing body on the second short side;
a third offset section connected to the second tab connection section and the second branch section; and
a plurality of fourth offset sections each having one end connected to the second branch section and the other end connected to each of the plurality of second exposed-surface connection sections.

15. The semiconductor device according to claim 13,
wherein the chip mounting section has a third long side extending in the first direction, a fourth long side opposite to the third long side, a third short side extending in the second direction, and a fourth short side opposite to the third short side in plan view,
the plurality of leads respectively include inner lead sections sealed in the sealing body and outer lead sections protruding from the sealing body,
the plurality of outer lead sections are arranged along the first long side and the second long side of the sealing body and are not arranged on the first short side and the second short side of the sealing body, and
the plurality of inner lead sections are arranged along the third long side, the fourth long side, and the third short side of the chip mounting section.

16. The semiconductor device according to claim 13,
wherein inclination angles of the first offset section and the plurality of second offset sections with respect to the chip mounting surface are less than 45 degrees.

17. The semiconductor device according to claim 13,
wherein the plurality of leads and a plurality of pads included in the semiconductor chip are electrically connected via a plurality of wires.

18. The semiconductor device according to claim 13,
wherein each of a plurality of pads included in the semiconductor chip is provided at a position lower than the plurality of leads with respect to the chip mounting surface.
